(19) United States
(12) Patent Application Publication
(10) Pub. No.: US 2024/0027220 A1
(43) Pub. Date: Jan. 25, 2024

(54) SIMULATION APPARATUS, SIMULATION METHOD, AND STORAGE MEDIUM

(71) Applicant: HONDA MOTOR CO.,LTD., Tokyo (JP)

(72) Inventor: Yusuke OKAMOTO, Saitama (JP)

(21) Appl. No.: 17/919,287

(22) PCT Filed: Dec. 17, 2021
(86) PCT No.: PCT/JP2021/046799

§ 371 Date: Oct. 17, 2022

(30) Foreign Application Priority Data
Dec. 18, 2020 (JP) 2020-210738
Dec. 18, 2020 (JP) 2020-210744

(51) Int. Cl. G01C 21/36; G01C 21/34

(52) U.S. Cl. CPC G01C 21/367; G01C 21/3469

(57) ABSTRACT

A simulation apparatus configured to perform a simulation of an arrangement of an energy recovery apparatus capable of recovering an accumulated energy amount of an energy accumulation apparatus is configured to: (a) output a first output amount which is an output amount related to a position at which the energy recovery apparatus is to be arranged; or (b) output a second output amount which is an output amount used for determining the position at which the energy recovery apparatus is to be arranged, based on at least one of: (i) a first relational expression; and (ii) a second relational expression.

### BACKGROUND

### 1. Technical Field

The present invention relates to a simulation apparatus, a simulation method, a program, and a storage medium.

### 2. Related Art

Patent Document 1 discloses that the number of charging replacement apparatuses to be arranged is determined according to an investable budget and a total initial cost. Patent Document 2 discloses that a charged state map is generated based on movable body information in which a charged state of a battery and location information indicating a location of a movable body are associated with each other.

### PRIOR ART DOCUMENTS

### Patent Documents

Patent Document 1: Japanese Patent Application Publication No. 2020-154586
Patent Document 2: WO No. 2020/027113

### GENERAL DISCLOSURE

According to a first aspect of the present invention, a simulation apparatus is provided. For example, the above-described simulation apparatus is configured to perform a simulation of an arrangement of an energy recovery apparatus capable of recovering an accumulated energy amount of an energy accumulation apparatus. For example, the above-described simulation apparatus includes: an output unit configured to output a result of the simulation. In the above-described simulation apparatus, for example, the output unit is configured to (a) output a first output amount which is an output amount related to a position at which the energy recovery apparatus is to be arranged based on at least one of (i) a first relational expression and (ii) a second relational expression. In the above-described simulation apparatus, for example, the output unit is configured to (b) output a second output amount which is an output amount used for determining the position at which the energy recovery apparatus is to be arranged based on at least one of (i) the first relational expression and (ii) the second relational expression. In the above-described simulation apparatus, for example, the first relational expression is a relational expression for deriving a cost of an owner or an operator of the energy recovery apparatus and which corresponds to a first variation amount that is a variation amount related to a position of the energy recovery apparatus. In the above-described simulation apparatus, the second relational expression is a relational expression for deriving a convenience of a user or a convenience of a movable body and which corresponds to the first variation amount and a second variation amount that is a variation amount related to dynamics of the user of the energy accumulation apparatus or to dynamics of the movable body configured to move by using energy of the energy accumulation apparatus.

In the above-described simulation apparatus, the first variation amount may include a plurality of the variation amounts related to a position of each of a plurality of the energy recovery apparatuses. In the above-described simulation apparatus, the first variation amount may be a first position which is the position of the energy recovery apparatus. In the above-described simulation apparatus, the second variation amount may be a second position which is a position of the user or the movable body when energy recovery demand of the energy accumulation apparatus arises. In the simulation apparatus, the second relational expression may be a relational expression for deriving the convenience, a degree of which varies along with a movement of the user or the movable body from the second position to the first position.

In the above-described simulation apparatus, the convenience may be indicated by an amount having a correlation with a difference between, at least one of, times, costs, and energies that are required for the movement in and movement distances in (i) a case where the user or the movable body moves along a first path that reaches a destination of the user or the movable body from the second position and (ii) a case where the user or the movable body moves along a second path that is a path different from the first path and that reaches the destination from the second position via the first position. In the above-described simulation apparatus, the convenience may be indicated by an amount having a correlation with a wait time which is a time during which the user or the movable body stands by for recovering the accumulated energy amount of the energy accumulation apparatus in the energy recovery apparatus, after the user or the movable body moves from the second position to the first position.

In the above-described simulation apparatus, the output unit may be configured to execute first processing for determining the position at which the energy recovery apparatus is to be arranged such that a first objective function including the first relational expression and the second relational expression is minimized or such that a value of the first objective function becomes smaller than a predetermined value. In the above-described simulation apparatus, (i) when a solution whose number is equal to or smaller than a predetermined number is obtained through the first processing, the output unit may be configured to output the first output amount based on the solution from the first processing. In the above-described simulation apparatus, (ii) when solutions whose number is more than the predetermined number are obtained through the first processing, the output unit may be configured to execute second processing for determining the position at which the energy recovery apparatus is to be arranged such that a second objective function placing more importance on the second relational expression than on the first relational expression as compared to the first objective function is minimized or such that a value of the second objective function becomes smaller than a predetermined value. The output unit may be configured to output the first output amount based on a solution from the second processing.

In the above-described simulation apparatus, the output unit may be configured to output the first output amount or the second output amount further based on a third relational expression which is a relational expression for deriving a safety of the energy accumulation apparatus and which corresponds to a third variation amount that is a variation amount related to a state of the energy accumulation apparatus. In the above-described simulation apparatus, the output unit may be configured to execute a program for calculating an optimum solution of an objective function including the first relational expression and the second relational expression, based on a simulation result obtained by simulating dynamics of the movable body that are in each of a plurality of candidate site areas set in a target zone as a target for the arrangement of the energy recovery apparatus and that are in a case where the movable body is capable of moving without considering a recovery of the accumulated energy amount of the energy accumulation apparatus. The output unit may be configured to output the first output amount or the second output amount based on the optimum solution.

The above-described simulation apparatus may include: a demand estimation unit configured to estimate energy recovery demand of the energy accumulation apparatus. The demand estimation unit may be configured to determine the second position based on a result of estimating the energy recovery demand. In the above-described simulation apparatus, the demand estimation unit may include an energy amount acquisition unit configured to acquire a remaining energy amount of the energy accumulation apparatus. In the above-described simulation apparatus, the demand estimation unit may include a demand arising position estimation unit configured to estimate a demand arising position which is a position at which the energy recovery demand has arisen, based on a low remaining amount position which is a position of the energy accumulation apparatus when the remaining energy amount of the energy accumulation apparatus acquired by the energy amount acquisition unit becomes equal to or smaller than a predetermined amount.

The above-described simulation apparatus may include: a deviation amount estimation unit configured to estimate a deviation amount which is a physical amount due to the movable body stopping by at a stop-by position based on (i) a destination location which is a location of a destination of the movable body and (ii) the stop-by position which is a position of the energy recovery apparatus capable of recovering the accumulated energy amount of the energy accumulation apparatus and at which the movable body has stopped by in movement to the destination. In the above-described simulation apparatus, the deviation amount estimation unit may be configured to estimate the deviation amount based on (i) a reference amount determined based on the demand arising position and the destination location and (ii) a stop-by amount determined based on the demand arising position, the stop-by position, and the destination location.

In the above-described simulation apparatus, the first variation amount may be the position of the energy recovery apparatus or the position and a number of the energy recovery apparatuses. The first relational expression may be a relational expression into which the first variation amount is input and which is for outputting at least one of an installation cost and an operational cost of the energy recovery apparatus. In the above-described simulation apparatus, at least one of the first relational expression and the second relational expression may constitute at least a part of an objective function of a mathematical programming problem for determining the position at which the energy recovery apparatus is to be arranged.

According to a second aspect of the present invention, a simulation method is provided. For example, the above-described simulation method is for performing a simulation of an arrangement of an energy recovery apparatus capable of recovering an accumulated energy amount of an energy accumulation apparatus. For example, the above-described simulation method includes: outputting a result of the simulation. In the above-described simulation method, for example, the outputting includes: (a) outputting a first output amount which is an output amount related to a position at which the energy recovery apparatus is to be arranged based on at least one of (i) a first relational expression and (ii) a second relational expression. In the above-described simulation apparatus, for example, the outputting includes: (b) outputting a second output amount which is an output amount used for determining the position at which the energy recovery apparatus is to be arranged based on at least one of (i) the first relational expression and (ii) the second relational expression. In the above-described simulation apparatus, for example, the first relational expression is a relational expression for deriving a cost of an owner or an operator of the energy recovery apparatus and which corresponds to a first variation amount that is a variation amount related to a position of the energy recovery apparatus. In the above-described simulation apparatus, the second relational expression is a relational expression for deriving a convenience of a user or a convenience of a movable body and which corresponds to the first variation amount and a second variation amount that is a variation amount related to dynamics of the user of the energy accumulation apparatus or to dynamics of the movable body configured to move by using energy of the energy accumulation apparatus. The respective steps of the above-described simulation method may be executed by a computer.

According to a third aspect of the present invention, a program is provided. For example, the above-described program is a program for causing a computer to function as the simulation apparatus according to the first aspect. For example, the above-described program is a program for causing a computer to execute the simulation method according to the second aspect.

According to a fourth aspect of the present invention, a computer-readable medium is provided. For example, the above-described computer-readable medium stores a program. The above-described computer-readable medium may store the above-described program according to the third aspect. The computer-readable medium may be a non-transitory computer-readable medium. The computer-readable medium may be a computer-readable recording medium.

The summary clause does not necessarily describe all necessary features of the embodiments of the present invention. The present invention may also be a sub-combination of the features described above.

### BRIEF DESCRIPTION OF THE DRAWINGS

FIG. 1 schematically shows an example of a system configuration of an arrangement assistance system 100.

FIG. 2 schematically shows an example of information stored in a storage unit 144.

FIG. 3 schematically shows an example of information processing in a recovery demand estimation unit 148.

FIG. 4 schematically shows an example of a deviation amount.

FIG. 5 schematically shows an example of the deviation amount.

FIG. 6 schematically shows an example of the deviation amount.

FIG. 7 schematically shows an example of the deviation amount.

FIG. 8 schematically shows an internal configuration example of the recovery demand estimation unit 148.

FIG. 9 schematically shows an internal configuration example of a deviation amount estimation unit 832.

FIG. 10 schematically shows an example of an output result of a demand output unit 842.

FIG. 11 schematically shows an example of an internal configuration of an optimum arrangement trial calculation unit 154.

FIG. 12 schematically shows an example of a data structure of dynamic data 1142.

FIG. 13 schematically shows an example of a data structure of optimum solution data 1144.

FIG. 14 schematically shows an example of information processing in the optimum arrangement trial calculation unit 154.

FIG. 15 schematically shows another example of the internal configuration of the optimum arrangement trial calculation unit 154.

FIG. 16 schematically shows an example of a data structure of optimum solution data 1544.

FIG. 17 schematically shows an example of a data structure of optimum solution data 1546.

FIG. 18 schematically shows an example of an output result 1800 of a trial calculation result output unit 1126.

FIG. 19 schematically shows an example of an output result 1900 of the trial calculation result output unit 1126.

FIG. 20 schematically shows an example of an internal configuration of an optimization solver 1124.

FIG. 21 schematically shows an example of an internal configuration of a simulation execution unit 2044.

FIG. 22 schematically shows an example of a system configuration of a computer 3000.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention. In the drawings, the same or similar parts are denoted by the same reference numerals, and redundant descriptions may be omitted.

[Overview of Arrangement Assistance System 100]

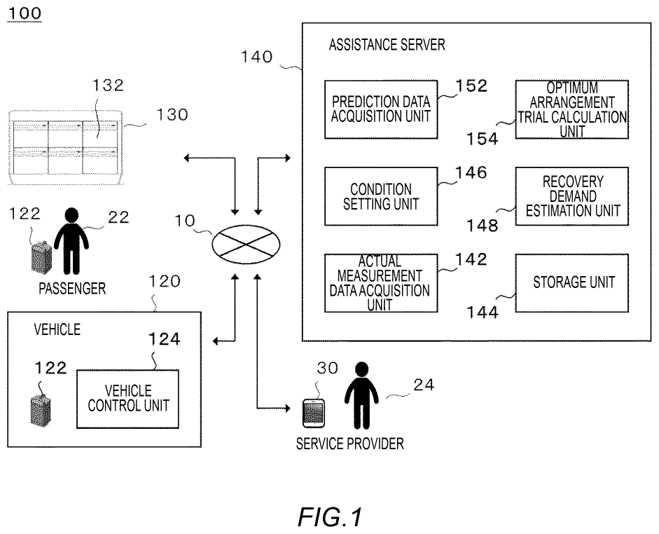

FIG. 1 schematically shows an example of a system configuration of an arrangement assistance system 100. In the present embodiment, the arrangement assistance system 100 includes a vehicle 120, a battery replacement apparatus 130, and an assistance server 140. In the present embodiment, the vehicle 120 includes a battery 122 and a vehicle control unit 124. In the present embodiment, the battery replacement apparatus 130 includes one or a plurality of (may simply be referred to as one or more) battery accommodation portions 132. In the present embodiment, the assistance server 140 includes an actual measurement data acquisition unit 142, a storage unit 144, a condition setting unit 146, a recovery demand estimation unit 148, a prediction data acquisition unit 152, and an optimum arrangement trial calculation unit 154.

In the present embodiment, the vehicle 120, the battery replacement apparatus 130, and the assistance server 140 are capable of mutually transmitting and receiving information via a communication network 10. Further, a service provider 24 who owns or operates the battery replacement apparatus 130 can access the assistance server 140 via the communication network 10 using a communication terminal 30.

In the present embodiment, an example of the arrangement assistance system 100 will be described in detail while taking, as an example, a case where a replacement type battery 122 is mounted on the vehicle 120, and the battery replacement apparatus 130 accommodates the battery 122 for replacement. Note that the arrangement assistance system 100 and the respective units thereof are not limited to the present embodiment.

According to the present embodiment, for example, when a remaining capacity of the battery 122 mounted on the vehicle 120 becomes small, a passenger 22 of the vehicle 120 causes the vehicle 120 to move to the nearest battery replacement apparatus 130. When the vehicle 120 arrives at the battery replacement apparatus 130, the passenger 22 requests the battery replacement apparatus 130 to lend out a charged battery 122, for example. When there is a lendable battery 122 in the battery replacement apparatus 130, the lending request of the passenger 22 is accepted. As a result, the passenger 22 is enabled to take out the charged battery 122 accommodated in the battery accommodation portion 132 of the battery replacement apparatus 130.

Next, the passenger 22 removes the battery 122 from the vehicle 120. The passenger 22 returns the battery 122 removed from the vehicle 120 to a return space of the battery 122, that is provided in the battery replacement apparatus 130, for example. Further, the passenger 22 takes out the charged battery 122 from the battery accommodation portion 132 of the battery replacement apparatus 130, and mounts the charged battery 122 on the vehicle 120. Accordingly, the battery 122 with a lowered remaining capacity is replaced by the charged battery 122.

Incidentally, by installing a larger number of battery replacement apparatuses 130 at positions where replacement demand of the battery 122 is high, a convenience, safety, and the like of the passenger 22 are improved. Further, a revenue of the service provider 24 is improved. On the other hand, there is an upper limit to a budget investable to the battery replacement apparatuses 130. Therefore, if the installation location and installation number of the battery replacement apparatuses 130 (may be referred to as arrangement of battery replacement apparatuses 130) can be determined in consideration of a balance between the convenience and safety of the passenger 22 and the revenue and budget of the service provider 24, large benefits can be obtained for both the passenger 22 and the service provider 24.

Herein, for determining the arrangement of the battery replacement apparatuses 130, a position at which the replacement demand of the battery 122 is high may be estimated using an actual movement history of the vehicle 120. However, when the passenger 22 wishes to replace the battery 122, the passenger 22 moves the vehicle 120 toward a position of an existing battery replacement apparatus 130. That is, the actual movement history of the vehicle 120 is affected by the position of the existing battery replacement apparatus 130. Therefore, a deviation is caused between a position at which the passenger 22 has wished to replace the battery 122 and a position at which the replacement demand of the battery 122 is high, which has been estimated using the actual movement history of the vehicle 120. For example, the position at which the replacement demand of the battery 122 is high, which has been estimated using the actual movement history of the vehicle 120, is closer to the existing battery replacement apparatus 130 than the position at which the passenger 22 has wished to replace the battery 122.

Therefore, development of a method of estimating the replacement demand of the battery 122 while suppressing the effect of the position of the existing battery replacement apparatus 130 is desired. In addition, development of a method of performing a trial calculation regarding the arrangement of the battery replacement apparatuses 130 in consideration of the balance between the convenience and safety of the passenger 22 and the revenue and budget of the service provider 24 is desired. Particularly, development of a method of determining the arrangement of the battery replacement apparatuses 130 while suppressing the effect of the position of the existing battery replacement apparatus 130 is desired.

According to one embodiment of the arrangement assistance system 100, for example, the assistance server 140 estimates the replacement demand of the battery 122. Specifically, the assistance server 140 first acquires information indicating a remaining capacity (may be referred to as SOC (State of Charge)) of the battery 122. Further, the assistance server 140 specifies the position of the battery 122 obtained when the remaining capacity of the battery 122 has become equal to or smaller than a predetermined amount (may be referred to as low remaining amount position). Next, the assistance server 140 estimates a position considered to be a position at which the passenger 22 has wished to replace the battery 122 based on the low remaining amount position. Accordingly, a position at which the replacement demand of the battery 122 has arisen (may be referred to as demand arising position) can be estimated. As a result, the assistance server 140 can estimate the replacement demand of the battery 122 while suppressing the effect of the position of the existing battery replacement apparatus 130.

According to another embodiment of the arrangement assistance system 100, for example, the assistance server 140 performs a trial calculation regarding the arrangement of the battery replacement apparatuses 130. Specifically, the assistance server 140 outputs, based on (i) a first condition which is a restriction condition related to a cost of the service provider 24 and (ii) a second condition which is a restriction condition related to a convenience of the passenger 22, (i) a first output value which is an output value related to the number of battery replacement apparatuses 130 to be arranged and (ii) a second output value which is an output value related to the position at which the battery replacement apparatus 130 is to be arranged. The first condition includes a first variation value which is a variation value related to the number of battery replacement apparatuses 130, for example. The second condition includes a second variation value which is a variation value related to the position of the passenger 22, for example. Accordingly, the assistance server 140 can perform the trial calculation regarding the arrangement of the battery replacement apparatuses 130 in consideration of the balance between the convenience and safety of the passenger 22 and the revenue and budget of the service provider 24.

[Overview of Elements Related to Arrangement Assistance System 100]

In the present embodiment, the communication network 10 may be a transmission path of wired communication, a transmission path of wireless communication, or a combination of the transmission path of wired communication and the transmission path of wireless communication. The communication network 10 may include a wireless packet communication network, the Internet, a P2P network, a dedicated line, a VPN, an electrical power line communication line, an inter-vehicle communication line, a road-to-vehicle communication line, and the like. The communication network 10 may also include (i) a mobile communication network such as a mobile phone line network, or may also include (ii) a wireless communication network such as a wireless MAN (for example, WiMAX (registered trademark)), a wireless LAN (for example, WiFi (registered trademark)), Bluetooth (registered trademark), Zigbee (registered trademark), or NFC (Near Field Communication).

In the present embodiment, the passenger 22 uses the battery 122. Specifically, the passenger 22 gets on the vehicle 120 and moves while consuming energy of the battery 122.

In the present embodiment, the service provider 24 owns or operates the battery replacement apparatus 130. The service provider 24 may use the arrangement assistance system 100 to determine the arrangement of the battery replacement apparatuses 130. The service provider 24 may be a natural person, a legal entity, or an association.

The communication terminal 30 is used by the service provider 24. For example, the communication terminal 30 functions as an interface between the arrangement assistance system 100 and the service provider 24. The communication terminal 30 only needs to be equipment capable of transmitting and receiving information to/from each unit of the arrangement assistance system 100 (for example, assistance server 140) via the communication network 10, and details thereof are not limited in particular. Examples of the communication terminal 30 may include a personal computer, a mobile terminal, and the like. Examples of the mobile terminal may include a mobile phone, a smartphone, a PDA, a tablet, a notebook computer or a laptop computer, a wearable computer, and the like.

The vehicle 120 moves while consuming energy of the battery 122. More specifically, the vehicle 120 moves while consuming electrical energy supplied from the battery 122. Examples of the vehicle 120 include an automobile, a motorcycle, a standing vehicle including a power unit, a railroad, and the like. Examples of the automobile include an electric automobile, a hybrid automobile, an electric cart, and the like. Examples of the motorcycle include a motorbike, an electric bicycle, and the like.

In the present embodiment, the battery 122 accumulates energy. More specifically, the battery 122 accumulates electrical energy. For example, the battery 122 accumulates electrical energy supplied from the battery replacement apparatus 130 while being accommodated in the battery replacement apparatus 130. Further, the battery 122 supplies electrical energy to the vehicle 120. As described above, in the present embodiment, the battery 122 is a replacement type or portable power storage apparatus and is attached while being attachable/detachable to/from the vehicle 120.

In the present embodiment, the vehicle control unit 124 controls the vehicle 120. For example, the vehicle control unit 124 acquires the position of the vehicle 120 from an own position estimation apparatus (not shown) provided in the vehicle 120. Further, the vehicle control unit 124 manages the remaining capacity of the battery 122. The vehicle control unit 124 may control communication between the vehicle 120 and each unit of the arrangement assistance system 100.

For example, the vehicle control unit 124 acquires a movement history of the vehicle 120 and transmits the movement history to the assistance server 140. The vehicle control unit 124 may transmit, to the assistance server 140, identification information used for the assistance server 140 to identify the vehicle 120 (may be referred to as vehicle ID) and the movement history in association with each other.

In one embodiment, the movement history of the vehicle 120 may be information indicating a variation of the position of the vehicle 120. The movement history of the vehicle 120 may be information in which one or more times and a position of the vehicle 120 at each time are associated with each other.

In another embodiment, a behavior of the vehicle 120 before the vehicle 120 reaches a destination since departing from a departure point is assumed to be one “movement”. In this case, the movement history of the vehicle 120 may be information in which positions of the departure point and destination and a departure time and arrival time are associated with each other, for each of the one or more movements.

The movement history of the vehicle 120 may be information in which positions of the departure point and destination, a movement path, and a departure time and arrival time are associated with one another, for each of the one or more movements. The movement path may be (i) information in which one or more times included in a period from the departure time to the arrival time and the position of the vehicle 120 at each time are associated with each other, or may be (ii) information in which identification information or position of each of one or more passing points (may be referred to as relay point, stop-by point, or the like) on a path from the departure point to the destination and a time at which the vehicle 120 has passed each passing point, are associated with each other.

Two consecutive “movements” are distinguished by ON/OFF of an ignition switch of the vehicle 120, for example. When a length of a parking time or stoppage time at a particular point is smaller than a predetermined value, it may be assumed that the particular point is a passing point instead of a destination.

For example, the vehicle control unit 124 acquires a history of the remaining capacity (may be referred to as remaining capacity history) of the battery 122 mounted on the vehicle 120, and transmits the remaining capacity history to the assistance server 140. The remaining capacity history of the battery 122 may be information in which one or more times and the remaining capacity of the battery 122 at each time are associated with each another. The vehicle control unit 124 may transmit, to the assistance server 140, the vehicle ID of the vehicle 120 and the remaining capacity history in association with each other.

The vehicle control unit 124 may transmit, to the assistance server 140, information in which (a) at least one of (i) the vehicle ID of the vehicle 120, (ii) identification information used for the assistance server 140 to identify the battery 122 mounted on the vehicle 120 (may be referred to as battery ID), and (iii) identification information used for the assistance server 140 to identify the passenger 22 of the vehicle 120 (may be referred to as user ID), (b) a time, (c) the position of the vehicle 120 at the time, and (d) the remaining capacity of the above-described battery 122 at the time, are associated with one another (may be referred to as probe information). Accordingly, the vehicle control unit 124 can transmit the movement history and the remaining capacity history to the assistance server 140.

In the present embodiment, in the battery replacement apparatus 130, the battery 122 is accommodated in the battery accommodation portion 132. Further, the battery replacement apparatus 130 supplies electrical energy to the battery 122 accommodated in the battery accommodation portion 132 to thus charge the battery 122.

In the present embodiment, the assistance server 140 assists generation of an arrangement plan of the battery replacement apparatuses 130 by the service provider 24. In one embodiment, the assistance server 140 outputs an estimation result on the replacement demand of the battery 122. In another embodiment, the assistance server 140 outputs a trial calculation result on the arrangement of the battery replacement apparatuses 130.

In the present embodiment, the actual measurement data acquisition unit 142 acquires actual measurement data related to dynamics of the passenger 22 or the vehicle 120 at a particular time point or period of the past (may be referred to as period). For example, the actual measurement data acquisition unit 142 acquires, as the actual measurement data, each of one or more pieces of probe information transmitted from each of the one or more vehicles 120 to the assistance server 140. The actual measurement data acquisition unit 142 stores the acquired actual measurement data in the storage unit 144, for example.

In the present embodiment, the storage unit 144 stores various types of information. In one embodiment, the storage unit 144 stores information to be used in the information processing in the assistance server 140. In another embodiment, the storage unit 144 stores information generated by the information processing in the assistance server 140. The storage unit 144 will be described later in detail.

In the present embodiment, the condition setting unit 146 accepts, from the communication terminal 30 used by the service provider 24, an input of conditions required for executing the information processing in the recovery demand estimation unit 148 or the optimum arrangement trial calculation unit 154. Further, various conditions are set based on the input from the service provider 24.

In the present embodiment, the recovery demand estimation unit 148 estimates the replacement demand of the battery 122. The recovery demand estimation unit 148 will be described later in detail.

In the present embodiment, the prediction data acquisition unit 152 acquires prediction data related to dynamics of the passenger 22 or the vehicle 120 in a particular period in the future. For example, the prediction data is generated by a simulation based on statistical information related to a future population, traffic, or the like in a particular zone. The prediction data acquisition unit 152 may acquire the above-described prediction data from another information processing apparatus. The prediction data acquisition unit 152 stores the acquired prediction data in the storage unit 144, for example.

In the present embodiment, the optimum arrangement trial calculation unit 154 performs a trial calculation regarding the arrangement of the battery replacement apparatuses 130. The optimum arrangement trial calculation unit 154 will be described later in detail.

[Detailed Configuration of Each Unit of Arrangement Assistance System 100]

Each unit of the arrangement assistance system 100 may be realized by hardware, software, or a combination of hardware and software. At least a part of the respective units of the arrangement assistance system 100 may be realized by a single server, or may be realized by a plurality of servers. At least a part of the respective units of the arrangement assistance system 100 may be realized on a virtual machine or a cloud system. At least a part of the respective units of the arrangement assistance system 100 may be realized by a personal computer or a mobile terminal. Examples of the mobile terminal may include a mobile phone, a smartphone, a PDA, a tablet, a notebook computer or a laptop computer, a wearable computer, and the like. The respective units of the arrangement assistance system 100 may store information using a distributed ledger technology such as blockchain or the like or a distributed network.

When at least a part of the components constituting the arrangement assistance system 100 is realized by software, the components realized by the software may be realized by activating software or a program defining operations related to the components in an information processing apparatus having a general configuration. The above-described information processing apparatus having a general configuration may include (i) a data processing apparatus having a processor such as a CPU or a GPU, a ROM, a RAM, a communication interface, and the like, (ii) an input apparatus such as a keyboard, a pointing device, a touch panel, a camera, a voice/sound input apparatus, a gesture input apparatus, various sensors, and a GPS receiver, (iii) an output apparatus such as a display apparatus, a voice/sound output apparatus, and a vibration apparatus, and (iv) a storage apparatus (including an external storage apparatus) such as a memory, an HDD, an SSD, and the like.

In the above-described information processing apparatus having a general configuration, the above-described data processing apparatus or storage apparatus may store the above-described software or program. Upon being executed by a processor, the above-described software or program causes the above-described information processing apparatus to execute operations stipulated by the software or program. The above-described software or program may also be stored in a non-transitory computer-readable recording medium. The above-described software or program may be a program for causing a computer to function as the arrangement assistance system 100 or a part thereof. The above-described software or program may be a program for causing a computer to execute an information processing method in the arrangement assistance system 100 or a part thereof.

In one embodiment, the information processing method in each unit of the arrangement assistance system 100 may be an estimation method for estimating energy recovery demand of the energy accumulation apparatus. The above-described estimation method includes acquiring a remaining energy amount of the energy accumulation apparatus, for example. The above-described estimation method includes, for example, estimating a demand arising position which is a position at which the energy recovery demand has arisen, based on a low remaining amount position which is a position of the energy accumulation apparatus when the remaining energy amount of the energy accumulation apparatus acquired in the acquiring the energy amount becomes equal to or smaller than a predetermined amount.

In another embodiment, the information processing method in each unit of the arrangement assistance system 100 may be a trial calculation method for performing a trial calculation regarding an arrangement of an energy recovery apparatus capable of recovering an accumulated energy amount of an energy accumulation apparatus. For example, the above-described trial calculation method includes outputting: (i) a first output value which is an output value related to the number of energy recovery apparatuses to be arranged; and (ii) a second output value which is an output value related to a position at which the energy recovery apparatus is to be arranged, based on: (i) a first condition which is a restriction condition related to a cost of an owner or an operator of the energy recovery apparatus; and (ii) a second condition which is a restriction condition related to a convenience of a user. The first condition includes, for example, a first variation value which is a variation value related to the number of energy recovery apparatuses. The second condition includes, for example, a second variation value which is a variation value related to a position of the user of the energy accumulation apparatus.

Further in another embodiment, the information processing method in each unit of the arrangement assistance system 100 may be a simulation method for performing a simulation of an arrangement of an energy recovery apparatus capable of recovering an accumulated energy amount of an energy accumulation apparatus. The above-described simulation method includes, for example, outputting a result of the simulation. In the above-described simulation method, for example, the outputting includes (a) outputting a first output amount which is an output amount related to a position at which the energy recovery apparatus is to be arranged based on at least one of (i) a first relational expression and (ii) a second relational expression. In the above-described simulation apparatus, for example, the outputting includes (b) outputting a second output amount which is an output amount used for determining the position at which the energy recovery apparatus is to be arranged based on at least one of (i) the first relational expression and (ii) the second relational expression. In the above-described simulation apparatus, for example, the first relational expression is a relational expression for deriving a cost of an owner or an operator of the energy recovery apparatus and which corresponds to a first variation amount that is a variation amount related to a position of the energy recovery apparatus. In the above-described simulation apparatus, the second relational expression is a relational expression for deriving a convenience of a user or a movable body and which corresponds to the first variation amount and a second variation amount that is a variation amount related to dynamics of the user of the energy accumulation apparatus or the movable body configured to move by using energy of the energy accumulation apparatus.

The passenger 22 may be an example of a moving person or the user. The service provider 24 may be an example of the owner or the operator. The vehicle 120 may be an example of the movable body. The battery 122 may be an example of the energy accumulation apparatus. The battery replacement apparatus 130 may be an example of the energy recovery apparatus. Each of the one or more battery accommodation portions 132 may be an example of the energy recovery apparatus. The assistance server 140 may be an example of the estimation apparatus or the trial calculation apparatus. The storage unit 144 may be an example of the position acquisition unit or the energy amount acquisition unit. The recovery demand estimation unit 148 may be an example of the estimation apparatus or the demand estimation unit. The optimum arrangement trial calculation unit 154 may be an example of the trial calculation apparatus.

The replacement of the battery 122 may be an example of energy recovery. The replacement demand of the battery 122 may be an example of the energy recovery demand. The remaining capacity of the battery 122 may be an example of the remaining energy amount. The position considered to be a position at which the passenger 22 has wished to replace the battery 122 may be an example of the demand arising position. The position at which the replacement demand of the battery 122 has arisen may be an example of the demand arising position.

### Example of Another Embodiment

In the present embodiment, an example of the arrangement assistance system 100 has been described in detail while taking, as an example, the case where the replacement type (may be referred to as portable type, removable type, or the like) battery 122 is used as an example of the energy accumulation apparatus that accumulates energy. Further, in the present embodiment, an example of the arrangement assistance system 100 has been described in detail while taking, as an example, the case where the battery replacement apparatus 130 replaces the battery 122 having a lowered remaining capacity by the charged battery 122 to recover the accumulated energy amount of the battery 122 used by the passenger 22 or the vehicle 120. However, the arrangement assistance system 100 is not limited to the present embodiment.

In another embodiment, the battery 122 may be configured such that it is fixed to the vehicle 120 and thus cannot be easily removed by the passenger 22. In this case, a charging apparatus may be used in place of the battery replacement apparatus 130. The charging apparatus may be an example of the energy recovery apparatus.

The battery replacement apparatus 130 receives a first battery 122 removed from the vehicle 120 and supplies a charged second battery 122. Further, the battery replacement apparatus 130 supplies electrical power to the first battery 122 removed from the vehicle 120 and charges the first battery 122. Meanwhile, for example, the charging apparatus is configured to supply electrical power to the battery 122 in a state where the battery 122 is mounted on the vehicle 120, to thus charge the battery 122. Accordingly, the charging apparatus can recover the accumulated energy amount of the battery 122 used by the passenger 22 or the vehicle 120.

In the present embodiment, an example of the vehicle 120 has been described in detail while taking the case where the vehicle 120 is an electric vehicle that moves by using electrical energy supplied from the battery 122, as an example. However, the vehicle 120 is not limited to the present embodiment. In another embodiment, the vehicle 120 may be an automobile, a motorcycle, a standing vehicle including a power unit, a railroad, or the like. Examples of the automobile include an automobile including an internal-combustion engine, an electric automobile, a fuel-cell automobile (FCV), a hybrid automobile, a compact commuter, an electric cart, and the like. Examples of the motorcycle include a motorbike, a motor tricycle, an electric bicycle, and the like.

In the present embodiment, an example of the arrangement assistance system 100 has been described in detail while taking the case where the battery 122 supplies electrical energy to the vehicle 120 as an example of the movable body, as an example. However, the movable body and energy are not limited to the present embodiment.

In another embodiment, the movable body may be a flight vehicle that moves in air, or may be a marine vessel that moves on or in water. Examples of the flight vehicle include an airplane, an air ship or a balloon, a hot-air balloon, a helicopter, a drone, and the like. Examples of the marine vessel include a ship, a hovercraft, a water bike, a submarine, a submersible craft, an underwater scooter, and the like. Further, the energy may be a fuel such as gasoline, diesel, hydrogen, or the like.

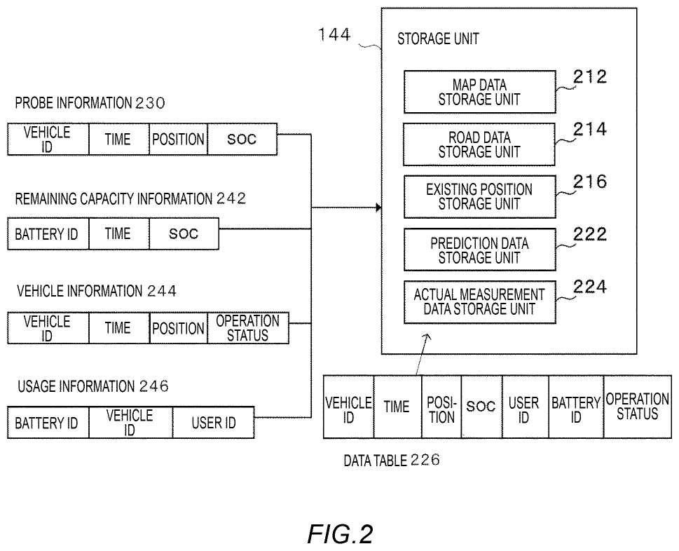

FIG. 2 schematically shows an example of information stored in the storage unit 144. In the present embodiment, the storage unit 144 includes a map data storage unit 212, a road data storage unit 214, an existing position storage unit 216, a prediction data storage unit 222, and an actual measurement data storage unit 224. In the present embodiment, the actual measurement data storage unit 224 stores a data table 226, for example.

In the present embodiment, the data table 226 stores, for example, a vehicle ID of the vehicle 120, a time, a position of the vehicle 120 at the time, an SOC of the battery 122 mounted on the vehicle 120 at the time, a user ID of a passenger 22 on the vehicle 120, a battery ID of the battery 122 mounted on the vehicle 120, and an operation status of the vehicle 120, in association with one another. Examples of the information indicating the operation status of the vehicle 120 include an electricity shortage flag that indicates that the remaining capacity of the battery 122 has become equal to or smaller than a predetermined value, a flag that indicates ON/OFF of the ignition switch, and the like.

In the present embodiment, the map data storage unit 212 stores map data. The map data includes, for example, image data for drawing a map, data indicating boundaries of administrative divisions, data indicating boundaries of virtual divisions set on the map (may be referred to as meshes or the like), or the like.

In the present embodiment, the road data storage unit 214 stores road data. The road data includes, for example, various types of information related to each of one or more road network links. Examples of the information related to the road network links include a node ID, a node position, a node length, a traffic amount, traffic control, presence or absence of traffic lights, a gradient, a road structure, and the like.

In the present embodiment, the existing position storage unit 216 stores information indicating a position of each of the one or more battery replacement apparatuses 130 that have already been installed. In the present embodiment, the prediction data storage unit 222 stores prediction data acquired by the prediction data acquisition unit 152. In the present embodiment, the actual measurement data storage unit 224 stores actual measurement data acquired by the actual measurement data acquisition unit 142.

In one embodiment, the actual measurement data storage unit 224 acquires one or more pieces of probe information 230 from each of the one or more vehicles 120, and stores the probe information 230 in the data table 226. Each of the one or more pieces of probe information 230 may correspond to each record of the data table 226.

In the present embodiment, the probe information 230 stores, for example, a vehicle ID of the vehicle 120, a time, a position of the vehicle 120 at the time, and an SOC of the battery 122 mounted on the vehicle 120 at the time, in association with one another. Note that as described above, the probe information 230 may include at least one of the user ID and the battery ID. Further, the probe information 230 may also include information indicating the operation status of the vehicle 120.

In another embodiment, the storage unit 144 acquires remaining capacity information 242 and vehicle information 244 from each of the one or more vehicles 120. Further, the storage unit 144 acquires usage information 246 from each of the one or more battery replacement apparatuses 130. The storage unit 144 stores the remaining capacity information 242, the vehicle information 244, and the usage information 246 in the data table 226. The storage unit 144 may generate a record of the data table 226 based on the remaining capacity information 242, the vehicle information 244, and the usage information 246.

In the present embodiment, the remaining capacity information 242 stores the battery ID, the time, and the SOC of the battery 122 at the time in association with one another. In the present embodiment, the vehicle information 244 stores a vehicle ID, a time, a position of the vehicle 120 at the time, and an operation status of the vehicle 120 at the time in association with one another. In the present embodiment, the usage information 246 stores a battery ID of the battery 122, a vehicle ID of the vehicle 120 on which the battery 122 is mounted, and a user ID of a passenger 22 on the vehicle 120 in association with one another.

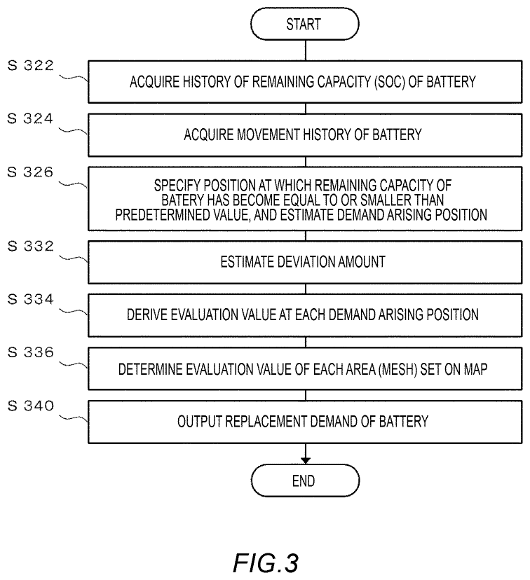

FIG. 3 schematically shows an example of information processing in the recovery demand estimation unit 148. According to the present embodiment, first, in S322, the recovery demand estimation unit 148 references the actual measurement data storage unit 224 and acquires a remaining capacity history of each of the one or more vehicles 120. The remaining capacity history indicates a remaining capacity of the battery 122 mounted on the vehicle 120 at each of one or more times.

Further, in S324, the recovery demand estimation unit 148 references the actual measurement data storage unit 224 and acquires a movement history of each of the one or more vehicles 120. The movement history indicates a position of the vehicle 120 at each of the one or more times, for example.

Next, in S326, the recovery demand estimation unit 148 specifies, for each of the one or more vehicles 120, a position at which the remaining capacity of the mounted battery 122 has become equal to or smaller than a threshold (as described above, may be referred to as low remaining amount position). Further, the recovery demand estimation unit 148 estimates a position at which replacement demand of the battery 122 has arisen (may be referred to as demand arising position) based on the low remaining amount position.

(i) When, before the vehicle 120 as a target of low remaining amount position specification processing and demand arising position estimation processing (may be referred to as target vehicle) arrives at a destination since departing from a departure point, the battery 122 of the target vehicle is replaced or charged, or (ii) when the battery 122 of the target vehicle is replaced or charged at the destination of the target vehicle, the recovery demand estimation unit 148 may carry out the above-described low remaining amount position specification processing and demand arising position estimation processing. On the other hand, (i) when, before a target vehicle arrives at a destination since departing from a departure point, the battery 122 of the target vehicle is not replaced or charged, or (ii) when the battery 122 of the target vehicle is not replaced or charged at the destination of the target vehicle, the recovery demand estimation unit 148 does not need to carry out the above-described low remaining amount position specification processing and demand arising position estimation processing. Accordingly, a calculation amount can be significantly decreased.

For example, in S324, when the recovery demand estimation unit 148 references the actual measurement data storage unit 224 to extract a movement history, the recovery demand estimation unit 148 extracts one or more movement histories matching (i) a condition that the battery 122 of the target vehicle has been replaced or charged before the target vehicle arrives at the destination since departing from the departure point, or (ii) a condition that the battery 122 of the target vehicle has been replaced or charged at the destination of the target vehicle. For example, by judging presence or absence of the battery replacement apparatus 130 on a movement path (including departure point and/or destination) of the target vehicle or judging whether the remaining capacity of the battery 122 of the target vehicle during a movement period has increased, whether the above-described conditions have matched can be judged.

In one embodiment, the recovery demand estimation unit 148 assumes that the passenger 22 wishes to replace the battery 122 at the low remaining amount position. In this case, the recovery demand estimation unit 148 estimates the low remaining amount position as the demand arising position. The above-described assumption is set by the condition setting unit 146, for example. The above-described threshold related to the remaining capacity is set by the condition setting unit 146, for example. The above-described threshold related to the remaining capacity may be determined based on at least one of a user ID, a time slot, a period, and a zone. For example, the condition setting unit 146 may set the above-described threshold for each user ID, may set the above-described threshold for each time slot, may set the above-described threshold for each period, or may set the above-described threshold for each zone.

In another embodiment, the recovery demand estimation unit 148 may specify the low remaining amount position or estimate the demand arising position based on (i) an access history with respect to a website related to a service for recovering energy of the battery 122 and/or (ii) an operation history of an application program (may be referred to as application) related to the service for recovering energy of the battery 122. The above-described application may be a program that operates on a communication terminal used by the passenger 22.

For example, the recovery demand estimation unit 148 estimates, as the demand arising position, a position of the vehicle 120 at a time the passenger 22 of the vehicle 120 has accessed the above-described web site or a time the passenger 22 of the vehicle 120 has operated the above-described application. When the passenger 22 of the vehicle 120 accesses the above-described web site or operates the above-described application to instruct execution of predetermined processing, the recovery demand estimation unit 148 may estimate the position of the vehicle 120 at a time the above-described search or reservation has been made, as the demand arising position. Examples of the above-described predetermined processing include processing of searching for the battery replacement apparatus 130 in the vicinity of the vehicle 120, processing of reserving a charged battery 122 accommodated in the battery replacement apparatus 130, and the like.

When the above-described website is accessed or the above-described application is operated in the vicinity of the low remaining amount position, the recovery demand estimation unit 148 may estimate the low remaining amount position or the position of the vehicle 120 at the above-described access time or operation time, as the demand arising position. When the above-described website is accessed or the above-described application is operated in the vicinity of a departure point location, the recovery demand estimation unit 148 may estimate the low remaining amount position or the position of the vehicle 120 at the above-described access time or operation time, as the demand arising position.

Further in another embodiment, the recovery demand estimation unit 148 may estimate, as the demand arising position, the position of the vehicle 120 at a time the passenger 22 of the vehicle 120 has confirmed the remaining capacity of the battery 122. For example, when an operation button for confirming the remaining capacity of the battery 122 is provided in the vehicle 120, the vehicle control unit 124 transmits, when the passenger 22 presses or clicks the operation button, information indicating that the passenger 22 has confirmed the remaining capacity of the battery 122 to the assistance server 140 as a part of the remaining capacity history, for example. Accordingly, the recovery demand estimation unit 148 can acquire a time at which the passenger 22 of the vehicle 120 has confirmed the remaining capacity of the battery 122. For example, when the assistance server 140 provides a service for confirming the remaining capacity of the battery 122 to the passenger 22 of the vehicle 120, the recovery demand estimation unit 148 may assume a time at which the passenger 22 of the vehicle 120 has accessed the assistance server 140 to request confirmation of the remaining capacity of the battery 122, as a time at which the passenger 22 of the vehicle 120 has confirmed the remaining capacity of the battery 122.

When the confirmation operation of the remaining capacity of the battery 122 is executed in the vicinity of the low remaining amount position, the recovery demand estimation unit 148 may estimate the low remaining amount position or the position of the vehicle 120 at the time the confirmation operation of the remaining capacity of the battery 122 is executed, as the demand arising position. When the confirmation operation of the remaining capacity of the battery 122 is executed in the vicinity of a departure point location, the recovery demand estimation unit 148 may estimate the low remaining amount position or the position of the vehicle 120 at the time the confirmation operation of the remaining capacity of the battery 122 is executed, as the demand arising position.

When the passenger 22 wishes to replace the battery 122, the passenger 22 causes the vehicle 120 to move to a position of a particular battery replacement apparatus 130 by deviating from an original movement path that leads to an original destination. After that, the passenger 22 causes the vehicle 120 to move toward the original destination via the battery replacement apparatus 130. Note that in the battery replacement apparatus 130, there may be a case where the passenger 22 cannot replace the battery 122.

As described above, when the passenger 22 or the vehicle 120 stops by at the battery replacement apparatus 130, a movement distance of the vehicle 120, a movement time of the vehicle 120, driving energy of the vehicle 120, and the like are required excessively due to the passenger 22 or the vehicle 120 stopping by at the battery replacement apparatus 130. The above-described physical amounts that are required excessively may be referred to as a deviation amount. The deviation amount will be described later in detail.

The inventors have focused on a possibility that, as the above-described deviation amount increases, the replacement demand of the battery 122 at the demand arising position will also increase. That is, the inventors have come up to estimate, by evaluating the replacement demand at the demand arising position using the above-described deviation amount, the replacement demand of the battery 122 while suppressing the effect of the position of the existing battery replacement apparatus 130.

Therefore, in S326, the recovery demand estimation unit 148 estimates the above-described deviation amount. Then, in S334, the recovery demand estimation unit 148 derives an evaluation value related to the replacement demand at each demand arising position based on the deviation amount at each demand arising position. Further, in S336, the recovery demand estimation unit 148 determines an evaluation value of each area set on a map based on the above-described evaluation value at each demand arising position.

After that, in S340, based on the evaluation value at each demand arising position or each area, the recovery demand estimation unit 148 outputs information indicating the replacement demand of the battery 122 at each demand arising position or each area. For example, the recovery demand estimation unit 148 outputs one or more maps in which the above-described evaluation values are superimposed on a map in various expression modes. Examples of the above-described expression modes include a heat map, a bubble chart, a summary value of the evaluation values for each area, and the like.

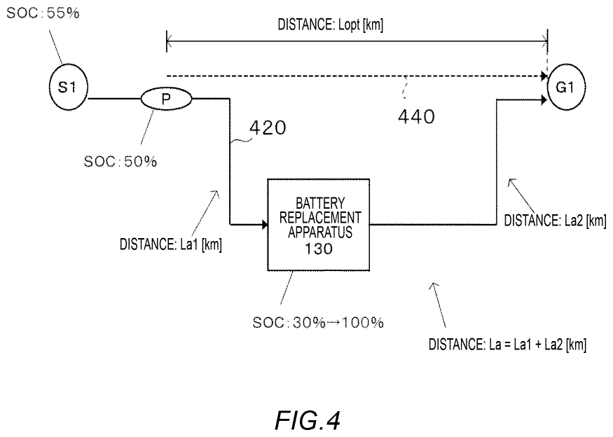

Using FIGS. 4, 5, 6, and 7, an example of the deviation amount described in relation to FIG. 3 will be described. In FIGS. 4 to 7, an example of the deviation amount will be described while taking a case where the deviation amount is a movement distance of the vehicle 120, as an example. Further, in FIGS. 4 to 7, an example of the deviation amount will be described while taking a case where the passenger 22 of the vehicle 120 wishes to replace the battery 122 at a position at which the SOC of the battery 122 mounted on the vehicle 120 has become 50%, as an example.

Note that in FIGS. 4 to 7, an example of the deviation amount will be described while taking a case where the physical amount expressing the deviation amount is a distance, as an example. However, it is to be noted that as described above, the physical amount expressing the deviation amount is not limited to the distance.

As shown in FIG. 4, the passenger 22 gets on the vehicle 120 and causes the vehicle 120 to move from a departure point S1 to a destination G1. At the departure point S1, the SOC of the battery 122 mounted on the vehicle 120 is, for example, 55%.

According to the present embodiment, after the vehicle 120 departs from the departure point S1, the SOC of the battery 122 becomes 50% at a point P on the way to the destination G1. Therefore, the passenger 22 determines to replace the battery 122 at a particular battery replacement apparatus 130 out of the one or more battery replacement apparatuses 130 installed in a periphery of the point P.

Then, the passenger 22 causes the vehicle 120 to move from the point P toward a position at which the above-described particular battery replacement apparatus 130 is installed. The passenger 22 stops by at the above-described particular battery replacement apparatus 130 and replaces the battery 122. By replacing the battery 122, the SOC of the battery 122 mounted on the vehicle 120 is increased from 30% to 100%, for example. After that, the passenger 22 causes the vehicle 120 to move from the above-described particular battery replacement apparatus 130 toward the destination G1 as the original destination.

In this case, a shortest path from the point P to the destination G1 is a path 440, and a distance of the path 440 is Lopt (km). On the other hand, a distance La (km) of a path 420 from the point P to the destination G1 via the battery replacement apparatus 130, that the passenger 22 or the vehicle 120 has actually traveled, is expressed as a sum of a distance La1 (km) from the point P to the battery replacement apparatus 130 and a distance La2 (km) from the battery replacement apparatus 130 to the destination G1. In this case, the deviation amount expressed by the distance becomes a difference between the distance of the path 420 and the distance of the path 440 (La−Lopt).

The location of the destination G1 may be an example of the destination location. The point P may be an example of the low remaining amount position or the demand arising position. The position of the particular battery replacement apparatus 130 may be an example of the stop-by position.

### Example of Another Embodiment

In the present embodiment, an example of the deviation amount has been described while taking the case where the path 420 is a path that the passenger 22 or the vehicle 120 has actually traveled, as an example. However, the deviation amount is not limited to the present embodiment. For example, the path 420 may be a shortest path from the point P to the destination G1 via the battery replacement apparatus 130.

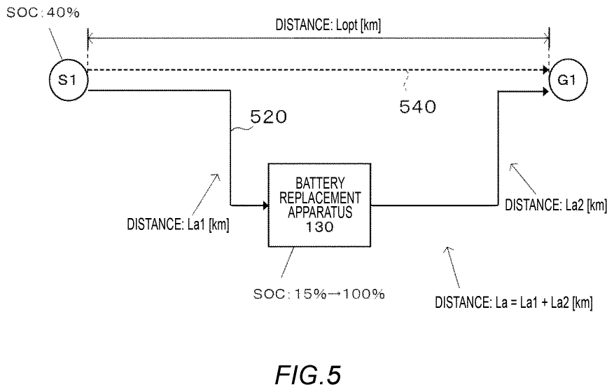

An embodiment to be described in relation to FIG. 5 is different from the embodiment described in relation to FIG. 4 in that the SOC of the battery 122 mounted on the vehicle 120 is 50% or less at the departure point S1. For example, according to the embodiment described in relation to FIG. 5, the SOC of the battery 122 mounted on the vehicle 120 is, for example, 40% at the departure point S1. Regarding other features, the embodiment to be described in relation to FIG. 5 may have a configuration similar to that of the embodiment described in relation to FIG. 4.

In the present embodiment, the passenger 22 determines to replace the battery 122 at a particular battery replacement apparatus 130 out of the one or more battery replacement apparatuses 130 installed in a periphery of the departure point S1. Then, the passenger 22 stops by at the above-described particular battery replacement apparatus 130 to replace the battery 122, and then departs for the destination G1.

In this case, a shortest path from the departure point S1 to the destination G1 is a path 540, and a distance of the path 540 is Lopt (km). On the other hand, a distance La (km) of a path 520 from the departure point S1 to the destination G1 via the battery replacement apparatus 130, that the passenger 22 or the vehicle 120 has actually traveled, is expressed as a sum of a distance La1 (km) from the departure point S1 to the battery replacement apparatus 130 and a distance La2 (km) from the battery replacement apparatus 130 to the destination G1. In this case, the deviation amount expressed by the distance becomes a difference between the distance of the path 520 and the distance of the path 540 (La−Lopt).

The location of the destination G1 may be an example of the destination location. The departure point S1 may be an example of the low remaining amount position or the demand arising position. The position of the particular battery replacement apparatus 130 may be an example of the stop-by position.

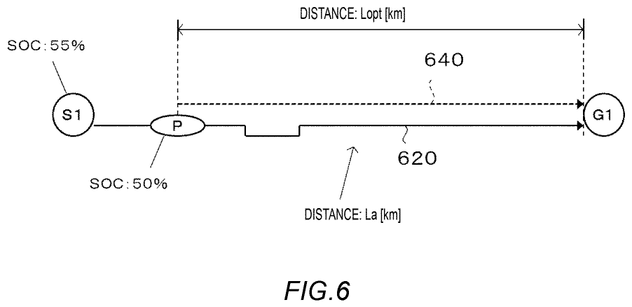

An embodiment to be described in relation to FIG. 6 is different from the embodiment described in relation to FIG. 4 in that, even when the SOC of the battery 122 becomes 50% at the point P, the passenger 22 moves toward the destination G1 without stopping by at the battery replacement apparatus 130. Regarding other features, the embodiment to be described in relation to FIG. 6 may have a configuration similar to that of the embodiment described in relation to FIG. 4.

In this case, a shortest path from the departure point S1 to the destination G1 is a path 640, and a distance of the path 640 is Lopt (km). On the other hand, a path from the departure point S1 to the destination G1, that the passenger 22 or the vehicle 120 has actually traveled, is a path 620, and a distance of the path 620 is La (km). In this case, the deviation amount expressed by the distance becomes a difference between the distance of the path 620 and the distance of the path 640 (La−Lopt). The deviation amount in the present embodiment is smaller than the deviation amount in the embodiment described in relation to FIG. 4. Accordingly, it can be seen that the deviation amount becomes smaller as the demand of the passenger 22, which is related to the replacement of the battery 122, becomes lower.

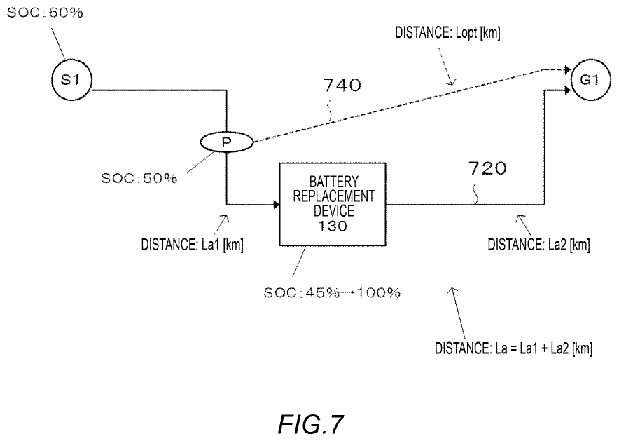

An embodiment to be described in relation to FIG. 7 corresponds to, for example, a case where the passenger 22 has intended to replace the battery 122 from before the SOC of the battery 122 becomes 50%. The embodiment to be described in relation to FIG. 7 is different from the embodiment described in relation to FIG. 4 in that the SOC of the battery 122 becomes 50% at a position closer to the battery replacement apparatus 130 than in the embodiment described in relation to FIG. 4. Regarding other features, the embodiment to be described in relation to FIG. 7 may have a configuration similar to that of the embodiment described in relation to FIG. 4.

In this case, a shortest path from the point P to the destination G1 is a path 740, and a distance of the path 740 is Lopt (km). On the other hand, a distance La (km) of a path 720 from the point P to the destination G1 via the battery replacement apparatus 130, that the passenger 22 or the vehicle 120 has actually traveled, is expressed as a sum of a distance La1 (km) from the point P to the battery replacement apparatus 130 and a distance La2 (km) from the battery replacement apparatus 130 to the destination G1. In this case, the deviation amount expressed by the distance becomes a difference between the distance of the path 720 and the distance of the path 740 (La−Lopt).

Herein, Lopt in the embodiment described in relation to FIG. 7 is larger than Lopt in the embodiment described in relation to FIG. 4. Further, La1 in the embodiment described in relation to FIG. 7 is smaller than La1 in the embodiment described in relation to FIG. 4. Therefore, the deviation amount in the embodiment described in relation to FIG. 7 is smaller than the deviation amount in the embodiment described in relation to FIG. 4. As described above, when the replacement demand of the battery 122 is estimated using actual measurement data in a case where the passenger 22 has intended to replace the battery 122 from before the SOC of the battery 122 becomes 50%, the estimation result is affected by the position of the existing battery replacement apparatus 130. Meanwhile, by estimating the replacement demand of the battery 122 using the deviation amount, the effect of the position of the existing battery replacement apparatus 130 can be suppressed.

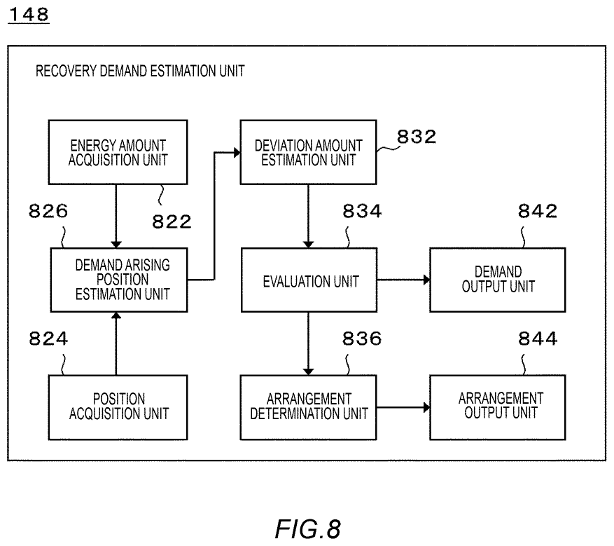

FIG. 8 schematically shows an internal configuration example of the recovery demand estimation unit 148. In the present embodiment, the recovery demand estimation unit 148 includes an energy amount acquisition unit 822, a position acquisition unit 824, a demand arising position estimation unit 826, a deviation amount estimation unit 832, an evaluation unit 834, an arrangement determination unit 836, a demand output unit 842, and an arrangement output unit 844.

In the present embodiment, the recovery demand estimation unit 148 analyzes the movement history of each of the one or more vehicles 120 and the remaining capacity history of the battery 122 mounted on each of the one or more vehicles 120, to derive the replacement demand of the battery 122 at each demand arising position or each area. The recovery demand estimation unit 148 calculates the deviation amount described above using, as one unit, a movement history from when an ignition switch of a particular vehicle 120 is turned ON to when the ignition switch of the particular vehicle 120 is turned OFF (may be referred to as analysis unit).

In the present embodiment, the energy amount acquisition unit 822 acquires a remaining capacity of the battery 122 mounted on the vehicle 120 to be analyzed. For example, the energy amount acquisition unit 822 acquires, for each of one or more analysis units, the remaining capacity of the battery 122 at each position of the analysis unit. The energy amount acquisition unit 822 may reference the data table 226 to acquire the above-described remaining capacity of the battery 122.

In the present embodiment, the position acquisition unit 824 acquires a position of the battery 122 mounted on the vehicle 120 to be analyzed. The position acquisition unit 824 may acquire the position of the passenger 22 or the vehicle 120 as the position of the battery 122. For example, the position acquisition unit 824 acquires, for each of the one or more analysis units, information indicating each position constituting the movement history of the vehicle 120, that is included in the analysis unit. Examples of the information indicating each position include a latitude and longitude of each position, an area ID for identifying an area to which each position belongs, and the like. The position acquisition unit 824 may reference the data table 226 to acquire the above-described information indicating each position.

In the present embodiment, the demand arising position estimation unit 826 estimates one or more demand arising positions for each of the one or more batteries 122. For example, the demand arising position estimation unit 826 analyzes one or more analysis units related to the one or more batteries 122, to estimate the one or more demand arising positions.

For example, the demand arising position estimation unit 826 judges whether a low remaining amount position is included in each of the one or more analysis units. Specifically, for each of the one or more analysis units, the demand arising position estimation unit 826 judges whether the remaining capacity of the battery 122 at each position, that has been acquired by the energy amount acquisition unit 822, is equal to or smaller than a predetermined amount. When there is a position at which the remaining capacity of the battery 122 is equal to or smaller than the predetermined amount in a particular analysis unit, the demand arising position estimation unit 826 judges that a low remaining amount position is included in the particular analysis unit.

Further, for the analysis unit including the low remaining amount position, the demand arising position estimation unit 826 determines the low remaining amount position based on the position of the battery 122 acquired by the position acquisition unit 824 and the remaining capacity of the battery 122 acquired by the energy amount acquisition unit 822. Specifically, a position at which the remaining capacity of the battery 122 becomes equal to or smaller than the predetermined amount for the first time is determined as the low remaining amount position.

The demand arising position estimation unit 826 estimates the demand arising position. The demand arising position estimation unit 826 may estimate the demand arising position based on the above-described low remaining amount position. As described above, in one embodiment, the demand arising position estimation unit 826 estimates the low remaining amount position as the demand arising position.

In another embodiment, as described above, the demand arising position estimation unit 826 may estimate the demand arising position based on (i) an access history with respect to a website related to a service for recovering energy of the battery 122 and/or (ii) an operation history of an application program related to the service for recovering energy of the battery 122. The demand arising position estimation unit 826 may estimate the demand arising position based on (a) the low remaining amount position and (b) (i) an access history with respect to a website related to a service for recovering energy of the battery 122 and/or (ii) an operation history of an application program related to the service for recovering energy of the battery 122.

Further in another embodiment, as described above, the demand arising position may be estimated based on a confirmation history of the remaining capacity of the battery 122 by the passenger 22. The demand arising position estimation unit 826 may estimate the demand arising position based on (a) the low remaining amount position and (b) the confirmation history of the remaining capacity of the battery 122 by the passenger 22.

In the present embodiment, the deviation amount estimation unit 832 estimates the deviation amount based on (i) a destination location which is a location of a destination of the passenger 22 or the vehicle 120 and (ii) a stop-by position which is a position of the battery replacement apparatus 130 at which the passenger 22 or the vehicle 120 has stopped by while moving to the destination. The deviation amount estimation unit 832 may estimate the deviation amount for each of the one or more demand arising positions related to each of the one or more batteries 122. For example, the deviation amount estimation unit 832 estimates the deviation amount based on (i) a reference amount determined based on the demand arising position and the destination location and (ii) a stop-by amount determined based on the demand arising position, the stop-by position, and the destination location. As described above, the deviation amount is related to at least one of the distance, time, and energy. The deviation amount estimation unit 832 will be described later in detail.

The deviation amount estimation unit 832 may change a deviation amount estimation procedure based on a state of the vehicle 120. For example, the deviation amount estimation unit 832 adjusts the demand arising position based on the state of the vehicle 120, to thus change a deviation amount calculation procedure.

For example, when the vehicle 120 is a service vehicle used in services of transportation, logistics, and the like, even if the remaining capacity of the battery 122 becomes smaller than a predetermined value while the service is in operation, there is a possibility that the passenger 22 of the vehicle 120 (for example, driver) will not be able to replace the battery 122 until ending the service.

In this case, the vehicle 120 travels on a path scheduled at departure and moves from the departure point S1 to the destination G1. Since the deviation amount becomes 0 by the procedure described above in a case where the vehicle 120 does not stop by at the battery replacement apparatus 130, the deviation amount estimation procedure is changed in such a case.

For example, when the vehicle 120 is executing the service at a time the replacement demand arises, the deviation amount estimation unit 832 estimates that a position at which the service has ended (may be referred to as service end position) after the rise of the replacement demand is the demand arising position, instead of the position at which the replacement demand has arisen. Then, the deviation amount estimation unit 832 estimates the deviation amount while the service end position is set as a point of origin.

In one embodiment, the deviation amount estimation unit 832 estimates the deviation amount of the vehicle 120 assuming that the vehicle 120 will replace the battery 122 using the battery replacement apparatus 130 nearest to the position at which the replacement demand has arisen (for example, low remaining amount position). As an example, the deviation amount estimation unit 832 derives a distance between the service end position and the position of the above-described battery replacement apparatus 130 (for example, La2 in FIG. 7) as the deviation amount.

According to another example, the deviation amount estimation unit 832 derives the deviation amount while considering weighting corresponding to at least one of (i) the distance between the service end position and the position of the above-described battery replacement apparatus 130 (may be referred to as replacement distance) and (ii) the remaining capacity of the battery 122 at the service end position. Specifically, the deviation amount estimation unit 832 calculates a drivable distance of the vehicle 120 (may be referred to as remaining traveling distance) based on the remaining capacity of the battery 122 at the service end position. Further, the deviation amount estimation unit 832 compares the above-described replacement distance and the remaining traveling distance of the vehicle 120.

When the replacement distance is larger than the remaining traveling distance of the vehicle 120, the vehicle 120 cannot use the battery replacement apparatus 130 nearest to the position at which the replacement demand has arisen to replace the battery 122. Therefore, the deviation amount estimation unit 832 estimates that, instead of the service end position, the departure point is the demand arising position. Then, the deviation amount estimation unit 832 estimates the deviation amount while the departure point is set as the point of origin. For example, the deviation amount estimation unit 832 derives, as the deviation amount, a distance between the position of the departure point and the position of the battery replacement apparatus 130 nearest to the position at which the replacement demand has arisen.

On the other hand, when the replacement distance is equal to or smaller than the remaining traveling distance of the vehicle 120, the vehicle 120 can use the battery replacement apparatus 130 nearest to the position at which the replacement demand has arisen to replace the battery 122. Therefore, the deviation amount estimation unit 832 derives the deviation amount such that the deviation amount increases as the replacement distance increases or a ratio of the replacement distance to the remaining traveling distance increases. For example, the deviation amount estimation unit 832 derives the deviation amount using a logarithm or a natural logarithm.

The deviation amount is derived using log (replacement distance/remaining traveling distance) or ln (replacement distance/remaining traveling distance). The deviation amount may also be derived by log (replacement distance/remaining traveling distance) or ln (replacement distance/remaining traveling distance). For example, the remaining traveling distance is calculated by a product of the drivable distance when the SOC is 100% and the SOC at the service end position. The drivable distance when the SOC is 100% is calculated by, for example, a battery capacity (Wh) when the SOC is 100%/electricity consumption (Wh/km).

In another embodiment, the deviation amount estimation unit 832 estimates the deviation amount of the vehicle 120 assuming that the vehicle 120 will use the battery replacement apparatus 130 nearest to the service end position to replace the battery 122. For example, the deviation amount estimation unit 832 derives, as the deviation amount, a distance between the service end position and a position of the above-described battery replacement apparatus 130. The deviation amount estimation unit 832 may derive the deviation amount while considering weighting by the distance between the service end position and the position of the battery replacement apparatus 130 nearest to the position at which the replacement demand has arisen (for example, La2 in FIG. 7).

For example, the deviation amount is calculated as a product of “the distance between the service end position and the position of the battery replacement apparatus 130 nearest to the service end position” and “a weight coefficient corresponding to the distance between the service end position and the position of the battery replacement apparatus 130 nearest to the position at which the replacement demand has arisen”. For example, the above-described weight coefficient is determined such that the weight coefficient increases as the distance between the service end position and the position of the battery replacement apparatus 130 nearest to the position at which the replacement demand has arisen increases.

In the present embodiment, the evaluation unit 834 derives an evaluation value of the demand arising position based on the deviation amount estimated by the deviation amount estimation unit 832. The evaluation unit 834 may derive the evaluation value for each of the above-described one or more demand arising positions.

The evaluation value is determined such that the evaluation value increases as the deviation amount increases, for example. In this case, the replacement demand of the battery 122 becomes higher as the evaluation value increases. The evaluation value may also be determined such that the evaluation value decreases as the deviation amount increases. In this case, the replacement demand of the battery 122 becomes higher as the evaluation value decreases.

Examples of the consideration elements for deriving the evaluation value include, in addition to (i) the deviation amount at the demand arising position described above, (ii) a distance between a stop-by position corresponding to a demand arising position and a destination location corresponding to the demand arising position, (iii) a minimum value of a distance between a destination location corresponding to a demand arising position and an existing battery replacement apparatus 130 in a periphery of the destination location, (iv) a minimum value of a distance between a demand arising position and an existing battery replacement apparatus 130 in a periphery of the demand arising position, (v) a remaining capacity of the battery 122 at a demand arising position, (vi) a remaining capacity of the battery 122 at a destination location corresponding to a demand arising position, (vii) a distance between a demand arising position and a destination location corresponding to the demand arising position, and the like. The evaluation unit 834 may derive the evaluation value at each demand arising position based on at least one of the plurality of consideration elements described above and a weight coefficient of each consideration element. The weight coefficients of the respective consideration elements may all be 1, or weight coefficients of at least a part of the consideration elements may be 1.

In one embodiment, the evaluation unit 834 derives, such that an evaluation value increases as a distance between a stop-by position corresponding to a demand arising position (for example, point P in FIG. 7) (for example, battery replacement apparatus 130 nearest to point P in FIG. 7) and a destination location corresponding to the demand arising position (for example, destination G1 in FIG. 7) (for example, La2 in FIG. 7) increases, an evaluation value at the demand arising position. In another embodiment, the evaluation unit 834 derives, such that an evaluation value increases as the remaining capacity of the battery 122 at a destination location corresponding to a demand arising position increases, an evaluation value at the demand arising position.

Further in another embodiment, the evaluation unit 834 may determine the evaluation value based on a combination of the above-described consideration elements. For example, the evaluation unit 834 derives an evaluation value at a demand arising position such that (i) an evaluation value decreases as a distance between a stop-by position corresponding to the demand arising position and a destination location corresponding to the demand arising position increases and (ii) an evaluation value increases as a remaining capacity of the battery 122 at a destination location corresponding to the demand arising position increases.

The evaluation unit 834 calculates a movable distance (may be referred to as remaining traveling distance) of the vehicle 120 at a destination location corresponding to a demand arising position based on, for example, a remaining capacity (Ah) of the battery 122 at the destination location corresponding to the demand arising position and (km/Ah) of the vehicle 120. For example, the evaluation unit 834 derives an evaluation value at a demand arising position such that an evaluation value increases as a ratio of (ii) a remaining traveling distance of the vehicle 120 at a destination location corresponding to the demand arising position to (i) a distance between a stop-by position corresponding to the demand arising position and the destination location corresponding to the demand arising position increases. The evaluation unit 834 may derive the evaluation value at the demand arising position such that the evaluation value increases as the above-described ratio approaches 1. The evaluation unit 834 may calculate the above-described evaluation value for data in which the above-described ratio becomes 0 or more and 1 or less.

For example, the evaluation unit 834 derives the evaluation value at the demand arising position such that the evaluation value increases as the replacement distance described above increases or a ratio of the replacement distance to the remaining traveling distance increases. The evaluation unit 834 may derive the evaluation value according to the above-described procedures when the replacement distance is equal to or smaller than the remaining traveling distance of the vehicle 120. For example, the evaluation unit 834 derives the evaluation value using a logarithm or a natural logarithm. For example, the evaluation value is derived using log (replacement distance/remaining traveling distance) or ln (replacement distance/remaining traveling distance). The evaluation value may also be derived by log (replacement distance/remaining traveling distance) or ln (replacement distance/remaining traveling distance). Since a value of replacement distance/remaining traveling distance is 1 or less when the replacement distance is equal to or smaller than the remaining traveling distance of the vehicle 120, the evaluation unit 834 can derive the evaluation value such that the evaluation value increases as the replacement distance increases or the ratio of the replacement distance to the remaining traveling distance increases.

Accordingly, for example, an evaluation value in a case where, when replacement demand arises for some reason, the vehicle 120 cannot stop by at the nearest battery replacement apparatus 130 by deviating from the scheduled path, can be calculated. Note that as described above, the deviation amount estimation unit 832 can change the deviation amount estimation procedure based on the state of the vehicle 120. When the deviation amount estimation unit 832 changes the deviation amount calculation procedure based on the state of the vehicle 120, the evaluation unit 834 may simply derive the evaluation value at the demand arising position based on the deviation amount estimated by the deviation amount estimation unit 832.

Further, the evaluation unit 834 may derive the evaluation value of each division based on evaluation values of one or more demand arising positions. The deviation amount estimation unit 832 may derive the evaluation value of each division by inputting the evaluation values of the one or more demand arising positions included in each division into a predetermined function. For example, the deviation amount estimation unit 832 derives the evaluation value of each division by adding the evaluation values of the one or more demand arising positions included in each division. In another embodiment, the above-described function may be a weighting function.

In the present embodiment, the arrangement determination unit 836 determines an arrangement of the battery replacement apparatuses 130. In one embodiment, the arrangement determination unit 836 determines a position at which each of the one or more battery replacement apparatuses 130 is to be arranged (may be referred to as candidate site) based on the demand arising positions estimated by the deviation amount estimation unit 832. For example, the arrangement determination unit 836 selects one or more candidate sites from the demand arising positions estimated by the deviation amount estimation unit 832 based on the evaluation values derived by the evaluation unit 834.

In another embodiment, the arrangement determination unit 836 may determine the position at which each of the one or more battery replacement apparatuses 130 is to be arranged based on the evaluation values of each area derived by the evaluation unit 834. For example, the arrangement determination unit 836 determines the number of battery replacement apparatuses 130 to be arranged inside each area based on the evaluation values derived by the evaluation unit 834. Further, the arrangement determination unit 836 selects one or more candidate sites from the one or more demand arising positions provided inside each area. The arrangement determination unit 836 may select one or more candidate sites based on the evaluation values derived by the evaluation unit 834.

In the present embodiment, the arrangement determination unit 836 may determine the positions at which the battery replacement apparatuses 130 are to be arranged further based on the positions of the battery replacement apparatuses 130 that have already been installed. For example, when another battery replacement apparatus 130 is already actually arranged within a geographic reach satisfying a predetermined condition, from a particular demand arising position, the arrangement determination unit 836 excludes the particular demand arising position from the above-described candidate sites.

Examples of the predetermined condition include (i) a condition that a movement distance between a demand arising position and an existing battery replacement apparatus 130 is smaller than a predetermined value, (ii) a condition that a statistical value or estimated value of a movement time from a demand arising position to an existing battery replacement apparatus 130 is smaller than a predetermined value, (iii) a condition that a statistical value or estimated value of energy to be consumed by a movement from a demand arising position to an existing battery replacement apparatus 130 is smaller than a predetermined value, and the like. The statistical value may be an average value.

In the present embodiment, the demand output unit 842 outputs information for displaying the replacement demand of the battery 122 on a map. For example, the demand output unit 842 outputs one or more maps obtained by superimposing the above-described evaluation values related to the replacement demand of the battery 122 on a map in various expression modes. Examples of the above-described expression modes include a heat map, a bubble chart, a summary value of evaluation values for each area, and the like.

In the present embodiment, the arrangement output unit 844 outputs information related to the arrangement of the battery replacement apparatuses 130. Examples of the information related to the arrangement of the battery replacement apparatuses 130 include information indicating installation location candidate sites of the battery replacement apparatuses 130, information indicating the number of battery replacement apparatuses 130 to be installed at each candidate site, information indicating an increase/decrease of the number of battery replacement apparatuses 130 at each candidate site, and the like.

Each position of the analysis unit may be an example of the position acquired by the position acquisition unit. Each area may be an example of each of a plurality of divisions each including a predetermined geographic reach. The another battery replacement apparatus 130 that is actually arranged may be an example of the existing energy recovery apparatus.

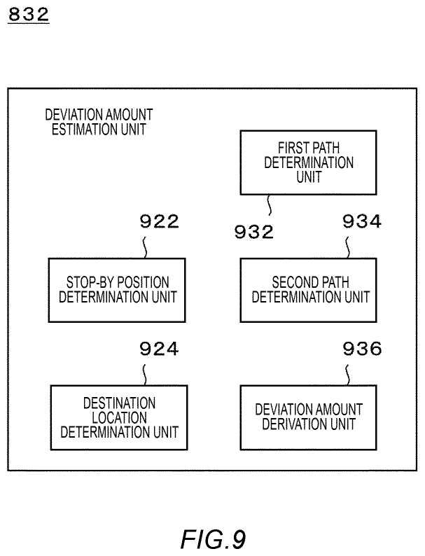

FIG. 9 schematically shows an internal configuration example of the deviation amount estimation unit 832. In the present embodiment, the deviation amount estimation unit 832 includes a stop-by position determination unit 922, a destination location determination unit 924, a first path determination unit 932, a second path determination unit 934, and a deviation amount derivation unit 936.

In the present embodiment, the stop-by position determination unit 922 determines a stop-by position which is a position of the battery replacement apparatus 130 at which the passenger 22 or the vehicle 120 has stopped by while moving to a destination. For example, for each of the one or more analysis units, the stop-by position determination unit 922 compares a position of the passenger 22 or the vehicle 120 and a position at which the existing battery replacement apparatus 130 is arranged. When a distance between the position of the passenger 22 or the vehicle 120 and the position at which the existing battery replacement apparatus 130 is arranged is smaller than a predetermined value, the stop-by position determination unit 922 determines the above-described position of the battery replacement apparatus 130 as a stop-by position.

In the present embodiment, the destination location determination unit 924 determines a destination location which is a location of a destination of the passenger 22 or the vehicle 120. For example, for each of the one or more analysis units, the destination location determination unit 924 determines a position at which the ignition switch is turned OFF as a target position.

In the present embodiment, the first path determination unit 932 determines, based on a demand arising position and a destination location, a first path used for the passenger 22 or the vehicle 120 to move from the demand arising position to the destination location. The first path determination unit 932 may use a path search algorithm similar to that used in a car navigation system to determine the first path.

The first path determination unit 932 may determine a reference amount for calculating a deviation amount based on the demand arising position and the destination location. For example, the first path determination unit 932 determines, as the reference amount, at least one of a distance, time, and energy in a case where the passenger 22 or the vehicle 120 moves from the demand arising position to the destination location along the first path.

In the present embodiment, the second path determination unit 934 determines a second path used for the passenger 22 or the vehicle 120 to move from the demand arising position to the destination location via the stop-by position, based on the demand arising position, the stop-by position, and the destination location. For example, the second path determination unit 934 determines, as the second path, a path used for moving from the demand arising position to the destination location via the stop-by position, that is indicated by the movement history of the vehicle 120. The second path determination unit 934 may use a path search algorithm similar to that used in a car navigation system to determine the second path.

The second path determination unit 934 may determine a stop-by amount for calculating a deviation amount based on the demand arising position, the stop-by position, and the destination location. For example, the second path determination unit 934 determines, as a stop-by amount, at least one of a distance, time, and energy in a case where the passenger 22 or the vehicle 120 moves from the demand arising position to the destination location via the stop-by position along the second path.

In the present embodiment, the deviation amount derivation unit 936 derives an estimated value of the deviation amount. For example, the deviation amount derivation unit 936 derives the estimated value of the deviation amount based on a difference between a physical amount for the passenger 22 or the vehicle 120 to move on the second path and a physical amount for the passenger 22 or the vehicle 120 to move on the first path. The above-described physical amount may be at least one of a distance, time, and energy.

Note that the deviation amount derivation unit 936 may derive an operating cost of the vehicle 120 based on at least one of the distance, time, and energy and a unit price of each physical amount. The deviation amount derivation unit 936 may derive the operating cost of the vehicle 120 as the deviation amount. Similarly, the first path determination unit 932 may determine, as the reference amount, an operating cost of the vehicle 120 in a case where the vehicle 120 moves from the demand arising position to the destination location along the first path. The second path determination unit 934 may determine, as the stop-by amount, the operating cost of the vehicle 120 in a case where the vehicle 120 moves from the demand arising position to the destination location via the stop-by position along the second path.

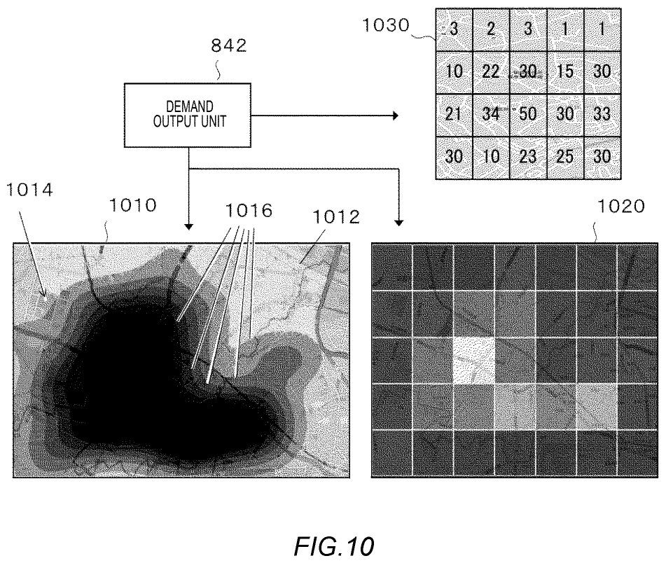

FIG. 10 schematically shows an example of an output result of the demand output unit 842. In the present embodiment, the demand output unit 842 outputs at least one map out of a map 1010, a map 1020, and a map 1030.

The map 1010 may be an example of the map obtained by superimposing the evaluation values of the respective demand arising positions or the respective areas on a map as a heat map. According to the present embodiment, the map 1010 is generated by superimposing a heat map 1014 on a map image 1012. Further, a heat map 1014 includes a plurality of contour lines 1016. Accordingly, a plurality of regions surrounded by two contour lines 1016 are formed inside the heat map 1014. Different colors or patterns are respectively formed in the plurality of regions.

Generally, the vehicle 120 travels on a road. Therefore, on the map 1010, one or more heat maps 1014 may be displayed along the road or on the road in a scattered manner. Further, as a traffic of the road increases, an accumulated value of deviation amounts increases. Therefore, on the map 1010, one or more heat maps 1014 in which a road having a high traffic is set as an apex of the contour line may be displayed.

The map 1020 may be an example of a map obtained by superimposing a plurality of objects corresponding to a plurality of areas on a map. At least one of a color, pattern, shape, and size of the object corresponding to each area is determined according to the evaluation value of each area. According to the present embodiment, translucent objects each having the same shape as the mesh of each area are superimposed on the map. Further, the color of the object corresponding to each area is determined according to the evaluation value of each area. According to the present embodiment, the plurality of objects corresponding to the respective areas and boundary lines of the respective areas are superimposed on the map.

The map 1030 may be an example of the map in which evaluation values of the respective areas are superimposed on the map such that the evaluation values are displayed inside meshes indicating boundaries of the respective areas. According to the present embodiment, such that the evaluation values of the respective areas are displayed inside the meshes indicating the boundaries of the respective areas, the evaluation values and boundary lines of the respective areas are superimposed on the map.

Note that a type of the map that can be output by the demand output unit 842 is not limited to the present embodiment. In another embodiment, the demand output unit 842 may output a map in which a bubble chart indicating the evaluation values of each area is superimposed on a map so as to be arranged at a center of each area.

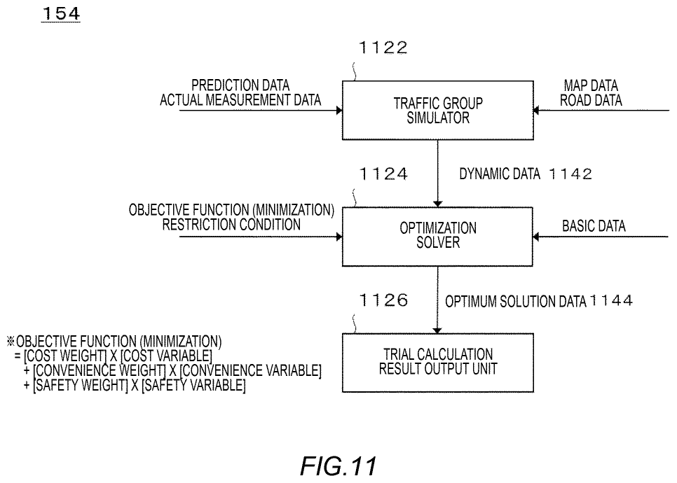

FIG. 11 schematically shows an example of an internal configuration of the optimum arrangement trial calculation unit 154. In the present embodiment, the optimum arrangement trial calculation unit 154 includes a traffic group simulator 1122, an optimization solver 1124, and a trial calculation result output unit 1126.

In the present embodiment, the traffic group simulator 1122 simulates, based on at least one of actual measurement data indicating dynamics of the passenger 22 or the vehicle 120 and prediction data, the movement of the passenger 22 or the vehicle 120 in a particular zone. For example, the traffic group simulator 1122 simulates dynamics of the passenger 22 or the vehicle 120 that are in each of a plurality of candidate site areas set in a target zone to be a target for arranging the battery replacement apparatuses 130 and that are in a case where the passenger 22 or the vehicle 120 can move without considering replacement of the battery 122. The traffic group simulator 1122 outputs, as the above-described simulation result, dynamic data 1142 which is traveling data of the passenger 22 or the vehicle 120 in a particular zone. The dynamic data 1142 will be described later in detail.

In the present embodiment, the traffic group simulator 1122 simulates dynamics of one or more passengers 22 or vehicles 120 without considering replacement of the battery 122. Therefore, an SOC 1226 of the battery 122 may be of a negative value. Further, the traffic group simulator 1122 uses map data and road data in the above-described particular zone to simulate the movement of the passenger 22 or the vehicle 120 such that the passenger 22 or the vehicle 120 travels on a shortest distance path from the departure point to the destination.

In the present embodiment, the optimization solver 1124 solves an optimization problem or a mathematical programming problem. The optimization problem or the mathematical programming problem is expressed by, for example, one or more objective functions and one or more restriction conditions.

Of a plurality of patterns related to the arrangement of one or more battery replacement apparatuses 130, the optimization solver 1124 outputs, as a solution to the optimization problem or the mathematical programming problem, a pattern in which the objective function matches a setting condition designated by a user of the optimization solver 1124. For example, the optimization solver 1124 derives a value of the objective function for all of the patterns for arranging m battery replacement apparatuses 130 in n areas, and determines a single or few patterns to become the solution based on the value of the objective function of each pattern. Note that an algorithm for reducing the number of patterns for which the value of the objective function is to be calculated to thus reduce a load of a computer may be mounted on the optimization solver 1124.

Examples of the above-described setting condition include a condition that the value of the objective function becomes maximum, a condition that the value of the objective function becomes minimum, a condition that the value of the objective function is included in a predetermined numerical range, and the like. An upper limit and lower limit do not need to be set in the above-described numerical range, or the upper limit and the lower limit may be set in the above-described numerical range. Further, when a plurality of objective functions are set, the above-described setting condition may be a combination of conditions respectively related to the plurality of objective functions.

### Example of Optimization Solver

For example, the optimization solver 1124 outputs, based on (i) a first condition which is a restriction condition related to a cost of the service provider 24 and (ii) a second condition which is a restriction condition related to a convenience of the passenger 22, (i) a first output value which is an output value related to the number of battery replacement apparatuses 130 to be arranged and (ii) a second output value which is an output value related to the positions at which the battery replacement apparatuses 130 are to be arranged. When there are no first output value nor second output value satisfying the first condition or the second condition, the optimization solver 1124 may output the first output value and the second output value so as to satisfy the second condition more preferentially than the first condition.

The first condition may include (i) a first variation value which is a variation value (may be referred to as variable) related to the number of battery replacement apparatuses 130. For example, the first condition includes a condition related to the first variation value. The above-described condition may be expressed by a mathematical expression. Examples of the first variation value include a land cost of an installation location, an electric utility rate at the installation location, a construction cost for installing the battery replacement apparatus 130, and the like.

For example, the land cost of the installation location is determined based on a land purchase unit price or rental unit price at the setting location and an installation area of the battery replacement apparatuses 130 that is determined by the installation number of the battery replacement apparatuses 130. For example, the electric utility rate at the setting location is determined based on a power unit price at the installation location and the number of battery accommodation portions 132 arranged in the battery replacement apparatus 130. For example, the construction cost for installing the battery replacement apparatuses 130 is determined based on a construction unit price at the installation location and the number of battery replacement apparatuses 130 to be installed at the installation location. Basic data such as the land purchase unit price or rental unit price, the power unit price, the construction unit price, or the like is set by the condition setting unit 146, for example.

The first condition may be a condition that a total cost related to the installation of the battery replacement apparatuses 130 is equal to or smaller than a predetermined price. The first condition may be a condition that a running cost of the battery replacement apparatuses 130 during a particular period is equal to or smaller than a predetermined price. The first condition may be a condition that a total cost related to the installation of the battery replacement apparatuses 130 is equal to or smaller than a predetermined price and a running cost of the battery replacement apparatuses 130 during a particular period is equal to or smaller than a predetermined price. The first condition may be a condition that an upper limit value of the number of battery replacement apparatuses 130 installable in a particular zone or at a particular point is equal to or smaller than a predetermined value.

The total cost related to the installation of the battery replacement apparatuses 130 may be an example of the first variation value. The running cost of the battery replacement apparatuses 130 during a particular period may be an example of the first variation value. The number of battery replacement apparatuses 130 installable in a particular zone or at a particular point may be an example of the first variation value.

The second condition may include a second variation value which is a variation value related to a position of the passenger 22. For example, the second condition includes a condition related to the second variation value. The above-described condition may be expressed by a mathematical expression. Examples of the second variation value include positional coordinates of the vehicle 120 that the passenger 22 is on, identification information of an area where the vehicle 120 that the passenger 22 is on is positioned (may be referred to as division, mesh, or the like), and the like.

The second condition may further include a third variation value which is a variation value related to the position of the battery replacement apparatus 130. For example, the second condition includes a condition related to the third variation value. The above-described condition may be expressed by a mathematical expression. Since the second condition includes the second variation value and the third variation value, the second condition can be used to express a degree of the convenience to be sacrificed due to the passenger 22 or the vehicle 120 stopping by at the battery replacement apparatus 130.

The second condition may be a condition that, during a unit period or a particular period, a length of a time during which the position of the passenger 22 is located inside a predetermined geographic reach (may be referred to as staying period) is equal to or larger than a predetermined value. The second condition may be a condition that, during a unit period or a particular period, a movement distance of the passenger 22 inside a predetermined geographic reach is equal to or larger than a predetermined value. The above-described length of the staying period and movement distance may be an example of the second variation value.

The third variation value may include a variation value related to a deviation movement time which is an excessive time that is due to the passenger 22 deviating from the original movement path and stopping by at the position of the battery replacement apparatus 130. The third variation value may include a variation value related to at least one of the excessive time, distance, or energy due to the passenger 22 deviating from the original movement path and stopping by at the position of the battery replacement apparatus 130 and the operating cost of the vehicle 120. The deviation amount described above may be an example of the third variation value.

The third variation value may include a variation value related to a wait time which is a standby time for the passenger 22 to replace the battery 122 in the battery replacement apparatus 130. The above-described wait time varies depending on an operation status of the battery replacement apparatus 130 in which the battery 122 is to be replaced. The second condition may be a condition that a length of the wait time in the battery replacement apparatus 130 is equal to or smaller than a predetermined value.

The optimization solver 1124 may output the above-described first output value and second output value based on (i) a first condition which is a restriction condition related to a cost of the service provider 24, (ii) a second condition which is a restriction condition related to a convenience of the passenger 22, and (iii) a third condition which is a restriction condition related to a safety of the battery 122. The third condition may include a fourth variation value which is a variation value related to a state of the battery 122. For example, the third condition includes a condition related to the fourth variation value. The above-described condition may be expressed by a mathematical expression.

Examples of the fourth variation value include (i) an SOC at a time of replacement, (ii) a difference between the SOC at the time of replacement and an SOC that the passenger 22 wishes to replace, and the like. When the SOC at the time of replacement is equal to or smaller than a predetermined threshold, a possibility that electricity shortage will occur increases as compared to a case where the SOC at the time of replacement is larger than the threshold. Further, when the difference between the SOC at the time of replacement and the SOC that the passenger 22 wishes to replace is larger than a predetermined threshold, a possibility that electricity shortage will occur increases as compared to a case where the difference is smaller than the threshold.

The third condition may be a condition that a minimum value of the SOC at the time of replacement is larger than a predetermined value. The third condition may be a condition that a difference between (a) (i) a value that the passenger 22 wishes as the value of the SOC at the time of replacement or (ii) a value predetermined as a value appropriate for the SOC at the time of replacement and (b) a value of the SOC at a time the battery 122 is actually replaced, is smaller than a predetermined value.

The optimization solver 1124 may execute a program for calculating an optimum solution of an objective function that includes the first variation value and the second variation value as variables, to output the first output value and the second output value. The optimization solver 1124 may also execute a program for calculating an optimum solution of an objective function that includes the first variation value, the second variation value, and the third variation value as variables, to output the first output value and the second output value. The optimization solver 1124 may also execute a program for calculating an optimum solution of an objective function that includes at least one of the first variation value, the second variation value, and the third variation value and the fourth variation value as variables, to output the first output value and the second output value.

For example, the objective function includes at least one of a first term related to a cost, a second term related to a convenience, and a third term related to a safety. For example, the objective function is expressed as “cost weight×cost variable”+“convenience weight×convenience variable”+“safety weight×safety variable”. When there are a plurality of cost variables, the cost weight may be determined for each of the cost variables, or cost weights with respect to two or more cost variables may be the same. When there are a plurality of convenience variables, the convenience weight may be determined for each of the convenience variables, or convenience weights with respect to two or more convenience variables may be the same. When there are a plurality of safety variables, the safety weight may be determined for each of the safety variables, or safety weights with respect to two or more safety variables may be the same.

At least one of the cost weight, the convenience weight, and the safety weight may be 0. At least one of the cost weight, the convenience weight, and the safety weight may be 1. For example, when the cost weight and the safety weight are set to 0 and the convenience weight is set to a value other than 0, the optimization solver 1124 outputs an optimum solution based on the value of the convenience variable.

An example of the cost variable is the above-described first variation value. An example of the convenience variable is the above-described second variation value and/or third variation value. An example of the safety variable is the above-described fourth variation value. As a method of calculating the above-described optimum solution, a well-known method may be adopted. Further, the above-described optimum solution means an optimum solution within a range of a predetermined calculation amount.

### Another Example of Optimization Solver

For example, the optimization solver 1124 (a) outputs a first output amount which is an output amount related to a position at which the battery replacement apparatus 130 is to be arranged, or (b) outputs a second output amount which is an output amount used for determining the position at which the battery replacement apparatus 130 is to be arranged, based on at least one of: (i) a first relational expression which is a relational expression for deriving a cost of the service provider 24 and which corresponds to a first variation amount which is a variation amount (may be referred to as variable) related to a position of the battery replacement apparatus 130; and (ii) a second relational expression which is a relational expression for deriving a convenience of the passenger 22 or the vehicle 120 and which corresponds to the first variation amount and a second variation amount which is a variation amount related to dynamics of the passenger 22 or the vehicle 120. The first variation amount may include a plurality of variation amounts related to the respective positions of the plurality of battery replacement apparatuses 130. The second variation amount may include a plurality of variation amounts related to the respective dynamics of the plurality of passengers 22 or vehicles 120.

The optimization solver 1124 may also output (a) the first output amount or (b) the second output amount based on at least one of: (i) the first relational expression; (ii) the second relational expression; and (iii) a third relational expression which is a relational expression for deriving a safety of the battery 122 and which corresponds to a third variation amount that is a variation amount related to a state of the battery 122. The optimization solver 1124 may also output (a) the first output amount or (b) the second output amount based on at least one of: (i) the first relational expression and (ii) the second relational expression; and (iii) the third relational expression. The third variation amount may include a plurality of variation amounts related to the respective states of the plurality of batteries 122.

The value of the first variation amount changes according to the position of the battery replacement apparatus 130. An example of the first variation amount is a position of each of the one or more battery replacement apparatuses 130 (may be referred to as first position). The first variation amount may include a plurality of variation amounts related to the respective positions of the plurality of battery replacement apparatuses 130.

Examples of the position of the battery replacement apparatus 130 include positional coordinates of the battery replacement apparatus 130, identification information of an area where the battery replacement apparatus 130 is positioned, and the like. The positional coordinates may be expressed by a latitude and longitude, or may be expressed by a latitude, longitude, and altitude.

If the position of each of the one or more battery replacement apparatuses 130 is determined, the number of the one or more battery replacement apparatuses 130 is also determined. Therefore, the number of the one or more battery replacement apparatuses 130 can be used as the first variation amount. The first variation amount may be information indicating the position of each of the one or more battery replacement apparatuses 130 and the number of the one or more battery replacement apparatuses 130.

The value of the second variation amount changes according to the dynamics of the passenger 22 or the vehicle 120. The dynamics of the passenger 22 or the vehicle 120 express a state where the vehicle 120 that the passenger 22 is on is moving or a state where a position of the vehicle 120 that the passenger 22 is on changes. Note that the dynamics of the passenger 22 or the vehicle 120 may express dynamics of the battery 122 mounted on the vehicle 120.

Examples of the second variation amount include (i) a position of the passenger 22 or the vehicle 120 at a particular time, (ii) a movement history of the passenger 22 or the vehicle 120, and the like. The position of the passenger 22 or the vehicle 120 at a particular time may be a position of the passenger 22 or the vehicle 120 at a time replacement demand of the battery 122 has arisen (may be referred to as second position). The second variation amount may include a plurality of variation amounts related to the respective dynamics of the plurality of passengers 22 or vehicles 120.

The dynamics of the passenger 22 or the vehicle 120 are determined based on actual movement data of the one or more vehicles, for example. The dynamics of the passenger 22 or the vehicle 120 may be a simulation result obtained by the traffic group simulator 1122.

The value of the third variation amount changes according to the state of the battery 122. Examples of the third variation amount include an SOC of the battery 122, a remaining capacity of the battery 122, a movable distance (for example, remaining traveling distance) of the vehicle 120, and the like. The third variation amount may include a plurality of variation amounts related to the respective states of the plurality of batteries 122.

The first relational expression is a relational expression for deriving an index value related to the cost of the service provider 24, and is expressed as, for example, a function of the first variation amount or a mathematical model that uses the first variation amount. The first relational expression may be a mathematical expression or a mathematical model for deriving the first variation value described above based on the position of each of the one or more battery replacement apparatuses 130.

For example, when the first variation amount is input to the first relational expression, at least one of the installation cost and the operational cost of the battery replacement apparatus 130 is output as a calculation result of the first relational expression. As described above, examples of the cost of the service provider 24 include a cost related to the installation (may be referred to as installation cost), a running cost, a total of these costs, and the like. Further, the cost of the service provider 24 varies according to the installation number of battery replacement apparatuses 130 and the installation location of each of the one or more battery replacement apparatuses 130. The first relational expression may include a term related to each of a plurality of items related to the cost of the service provider 24.

The first relational expression may include one or more mathematical expressions or mathematical models for deriving the installation cost of each of the one or more battery replacement apparatuses 130. The total cost related to the installation of the one or more battery replacement apparatuses 130 is derived as a sum of the respective installation costs of the one or more battery replacement apparatuses 130, for example. The first relational expression may include one or more mathematical expressions or mathematical models for deriving the running cost of each of the one or more battery replacement apparatuses 130. The total running cost of the one or more battery replacement apparatuses 130 is derived as a sum of the respective running costs of the one or more battery replacement apparatuses 130, for example.

The second relational expression is a relational expression for deriving an index value related to the convenience of the passenger 22 or the vehicle 120, and is expressed as, for example, a function of the first variation amount and the second variation amount or a mathematical model that uses the first variation amount and the second variation amount. The second relational expression may be a relational expression for deriving a convenience, a degree of which varies along with the movement of the passenger 22 or the vehicle 120 from the second position to the first position. Example of such a convenience include the deviation amount described above, the wait time, and the like.

In one embodiment, the convenience is indicated by an amount having a correlation with a difference between, at least one of, times, costs, and energies that are required for the movement in and movement distances in (i) a case where the passenger 22 or the vehicle 120 moves along a first path that reaches a destination of the user or the movable body from the second position and (ii) a case where the passenger 22 or the vehicle 120 moves along a second path that is a path different from the first path and that reaches the destination from the second position via the first position (for example, the deviation amount described above). In another embodiment, the convenience is indicated by an amount having a correlation with a wait time which is a time during which the passenger 22 or the vehicle 120 stands by for recovering the SOC of the battery 122 in the battery replacement apparatus 130, after the passenger 22 or the vehicle 120 moves from the second position to the first position.

The second relational expression may be a mathematical expression or mathematical model for deriving the third variation value or deviation amount described above and/or the wait time, based on the position of each of the one or more battery replacement apparatuses 130 and a movement history of each of the one or more passengers 22 or vehicles 120. As described above, the movement history of each of the one or more passengers 22 or vehicles 120 may be real data, prediction data, data generated based on real data and/or prediction data, or a simulation result.

The second relational expression may include a mathematical expression or a mathematical model for deriving an accumulated value of the third variation values or deviation amounts and/or the wait times during a particular period, for each of the one or more passengers 22 or vehicles 120. The third variation value or deviation amount and/or the wait time of the one or more passengers 22 or vehicles 120 is/are derived as a sum of the above-described accumulated values respectively related to the one or more passengers 22 or vehicles 120, for example. The second relational expression may include a term related to various deviation amounts or a term related to the wait time.

The third relational expression is a relational expression for deriving an index value related to the safety of the battery 122, and is expressed as, for example, a function of the third variation amount or a mathematical model that uses the third variation amount. The third relational expression may be a mathematical expression or a mathematical model for deriving the fourth variation value described above based on the one or more batteries 122. The third relational expression may include a term related to each of a plurality of items related to the safety.

As described above, the optimization solver 1124 outputs, out of a plurality of patterns related to the arrangement of the one or more battery replacement apparatuses 130 (may be referred to as arrangement patterns), as a solution to the optimization problem or the mathematical programming problem, a single or few arrangement patterns in which the objective function matches a setting condition designated by the user of the optimization solver 1124. For example, the optimization solver 1124 executes a program for calculating an optimum solution of an objective function including the first relational expression and the second relational expression, based on a simulation result obtained by simulating dynamics of the vehicle 120 that are in each of a plurality of candidate site areas set in a target zone to be a target for arranging the battery replacement apparatuses 130 and that are in a case where the vehicle 120 can move without considering replacement of the battery 122. Further, the optimization solver 1124 outputs the first output amount or the second output amount based on the optimum solution.

The objective function includes at least one of a first term related to the cost, a second term related to the convenience, and a third term related to the safety. In this case, the first relational expression may constitute at least a part of the first term related to the cost. The second relational expression may constitute at least a part of the second term related to the convenience. The third relational expression may constitute at least a part of the third term related to the safety.

In one embodiment, the optimization solver 1124 outputs, as the first output amount, information indicating an arrangement pattern that has been determined as a solution to the optimization problem or the mathematical programming problem. The optimization solver 1124 may output information indicating a single arrangement pattern to be the optimum solution, or may output information indicating a plurality of arrangement patterns matching the setting condition. The first output amount may further include a calculation result of the objective function corresponding to each arrangement pattern.

The first output amount may further include an index calculation result indicating an order (may be referred to as priority) of the one or more battery replacement apparatuses 130 in each arrangement pattern. For example, the above-described order is determined based on (i) a calculation result of an index designated as KPI, (ii) a maximum value of an absolute value of a difference between a value of an objective function in a pattern output as a solution and a value of an objective function in a pattern in which the arrangements of the battery replacement apparatuses 130 other than a particular battery replacement apparatus 130 are the same and a position of the particular battery replacement apparatus 130 is in an adjacent area, or the like. Examples of the above-described KPI include (i) the number of times the battery replacement apparatus 130 is used during a period calculated by the optimization solver 1124, (ii) a calculation result of at least one of the first relational expression, the second relational expression, and the third relational expression, (iii) a calculation result of a term included in at least one of the first relational expression, the second relational expression, and the third relational expression, and the like.

The arrangement pattern determined as the solution to the optimization problem or the mathematical programming problem indicates the positions at which the one or more battery replacement apparatuses 130 are to be arranged. Examples of the information indicating the arrangement pattern include (i) information indicating a position of each of the one or more battery replacement apparatuses 130, (ii) information indicating the number of battery replacement apparatuses 130 to be arranged in each of the one or more areas, (iii) information indicating identification information of an area where the battery replacement apparatus 130 is to be arranged out of the one or more areas and the number of battery replacement apparatuses 130 to be arranged in each area, (iv) identification information for identifying each of all of the patterns for which objective function derivation processing has been executed in the optimization solver 1124 (may be referred to as trial number), and the like. According to the present embodiment, the arrangement pattern optimized by the optimization solver 1124 is presented to a user of the assistance server 140.

For example, first, the optimization solver 1124 executes first processing for determining the positions at which the battery replacement apparatuses 130 are to be arranged such that a first objective function including the first relational expression and the second relational expression is minimized or such that a value of the first objective function becomes smaller than a predetermined value. When solutions in a number equal to or smaller than a predetermined number are obtained by the above-described first processing, the optimization solver 1124 outputs the first output amount based on the solutions of the first processing. On the other hand, when solutions in a number larger than the predetermined number are obtained by the above-described first processing, the optimization solver 1124 executes second processing for determining the positions at which the battery replacement apparatuses 130 are to be arranged such that a second objective function that places more importance on the second relational expression than the first relational expression as compared to the first objective function, is minimized, or such that a value of the second objective function becomes smaller than a predetermined value. Further, the optimization solver 1124 outputs the first output amount based on solutions of the second processing.

In another embodiment, for each of the one or more arrangement patterns determined as a solution to the optimization problem or the mathematical programming problem, the optimization solver 1124 outputs, as the second output amount, information indicating a calculation result of at least one of the first relational expression, the second relational expression, the third relational expression, and terms included in these expressions. The second output amount may further include information indicating the arrangement pattern.

These pieces of information are used to determine the positions at which the one or more battery replacement apparatuses 130 are to be arranged. According to the present embodiment, various calculation results related to each of the plurality of arrangement patterns output by the optimization solver 1124 are presented to the user of the assistance server 140. Upon confirming the presented data, the user of the assistance server 140 can extract an arrangement pattern considered to be appropriate from the plurality of arrangement patterns.

The optimization solver 1124 may output optimum solution data 1144 by executing, based on dynamic data 1142 as a simulation result of the traffic group simulator 1122, a program for calculating an optimum solution of the objective function that includes the first variation value and the second variation value as variables. The optimum solution data 1144 may include the first output value and the second output value. The optimization solver 1124 may output the first output value and the second output value by executing, based on the dynamic data 1142 as a simulation result of the traffic group simulator 1122, a program for calculating an optimum solution of the objective function that includes at least one of the first variation value, the second variation value, and the third variation value and the fourth variation value as variables. Details of the procedure for the optimization solver 1124 to output the first output value and the second output value using the dynamic data 1142 will be described later.

The standby time for replacing the battery 122 may be an example of the standby time for recovering the accumulated energy amount of the energy accumulation apparatus. The dynamic data 1142 may be an example of the simulation result.

In the present embodiment, the trial calculation result output unit 1126 outputs a trial calculation result. For example, the trial calculation result output unit 1126 outputs information related to the arrangement of the battery replacement apparatuses 130. Examples of the information related to the arrangement of the battery replacement apparatuses 130 include information indicating a candidate site of an installation location of the battery replacement apparatus 130, information indicating the number of battery replacement apparatuses 130 to be installed at each candidate site, information indicating an increase/decrease of the number of battery replacement apparatuses 130 at each candidate site, and the like.

The optimization solver 1124 may be an example of the output unit. The trial calculation result output unit 1126 may be an example of the output unit.

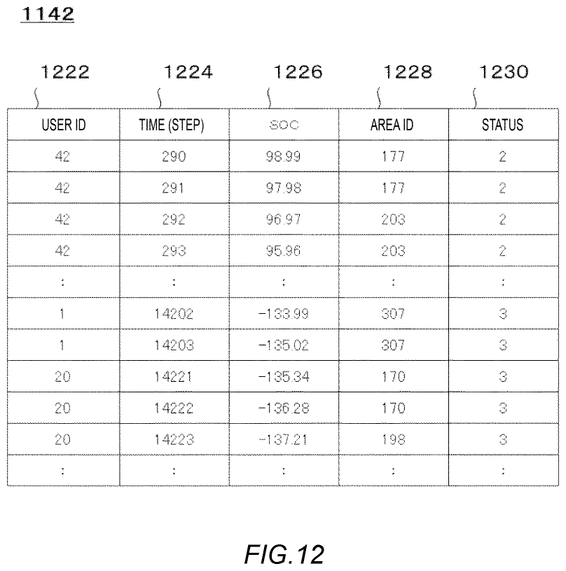

FIG. 12 schematically shows an example of a data structure of the dynamic data 1142. In the present embodiment, the dynamic data 1142 stores (i) a user ID 1222, (ii) a time 1224, (iii) an SOC 1226 of a battery 122 mounted on a vehicle 120 used by a passenger 22 indicated by the user ID 1222 at the time 1224, (iv) an area ID 1228 for identifying an area where the above-described passenger 22 or vehicle 120 is positioned at the time 1224, and (v) a status 1230 of the above-described battery 122, in association with one another. The dynamic data 1142 may include a vehicle ID in place of the user ID 1222.

In the present embodiment, the time 1224 may be identification information by hours (may be referred to as steps) in a simulation of the traffic group simulator 1122. As described above, in the traffic group simulator 1122, the dynamics of the one or more passengers 22 or vehicles 120 are simulated without considering replacement of the battery 122. Therefore, the SOC 1226 of the battery 122 may be of a negative value. In the present embodiment, the status 1230 indicates a section determined according to a category of the movement of the vehicle 120. A number, a symbol, or the like for identifying the above-described section determined according to the category of the movement may be input to the status 1230. Examples of the category of the movement of the vehicle 120 include a movement from home, a movement to home, a movement while a service is in operation, a movement while being out of service, and the like.

For example, when the departure point of the vehicle 120 is home or a place that is highly likely home, the category of the movement is determined as a movement from home. For example, when the destination of the vehicle 120 is home or a place that is highly likely home, the category of the movement is determined as a movement to home. For example, when the vehicle 120 is used for a delivery service, a transportation service, or the like, it is determined that the service is in operation during a period in which the vehicle 120 moves while carrying goods or a person as a target of the service, a period in which the vehicle 120 moves to a designated location for executing the service, or the like. On the other hand, during a period in which the vehicle 120 moves toward a standby location upon completing the service, it is determined as being out of service.

Various settings in the optimization solver 1124 may be adjusted according to the type of the movement indicated by the status 1230. For example, a restriction condition in the optimization solver 1124 is adjusted according to the type of the movement indicated by the status 1230. For example, whether to replace the battery 122, the priority, or the like is set in the optimization solver 1124 according to the type of the movement indicated by the status 1230.

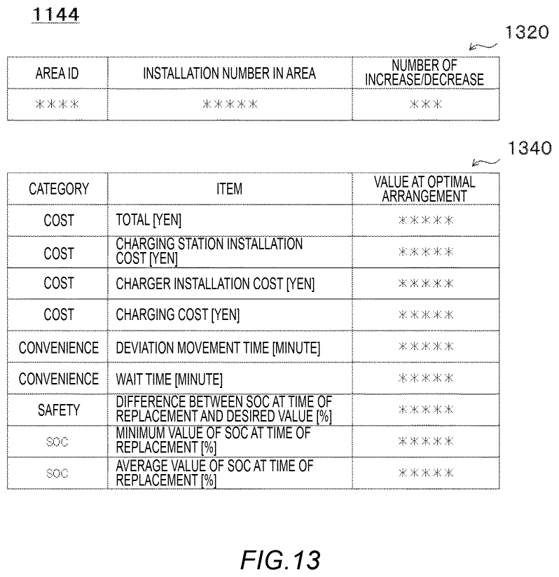

FIG. 13 schematically shows an example of a data structure of the optimum solution data 1144. In the present embodiment, the optimum solution data 1144 includes arrangement trial calculation data 1320 and breakdown data 1340.

In the present embodiment, the arrangement trial calculation data 1320 stores an area ID of each area, the number of battery replacement apparatuses 130 to be installed inside each area, and the increased/decreased number of battery replacement apparatuses 130 in each area, in association with one another. In the present embodiment, the breakdown data 1340 indicates a value of each item constituting an objective function in an optimum solution. In the present embodiment, the breakdown data 1340 stores a name of the above-described each item, a category into which each item is categorized, and a value of each item, in association with one another.

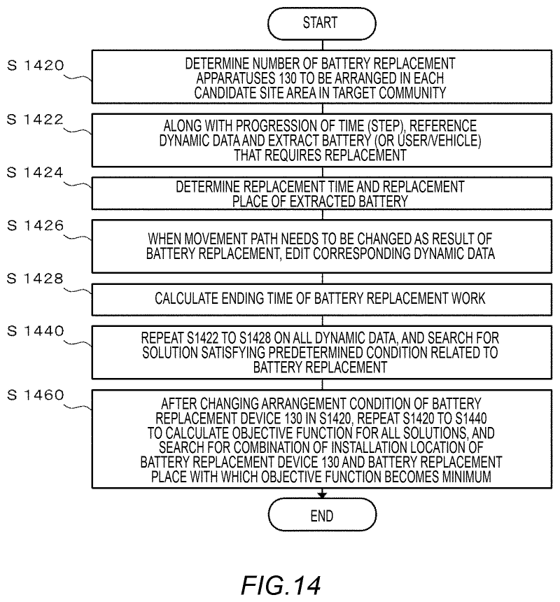

FIG. 14 schematically shows an example of information processing in the optimum arrangement trial calculation unit 154. As described above, the optimization solver 1124 of the optimum arrangement trial calculation unit 154 outputs a solution to an optimization problem for installing m battery replacement apparatuses 130 (as described above, may be referred to as mathematical programming problem) in a target zone divided into n areas. Herein, n and m are positive integers. Further, the trial calculation result output unit 1126 of the optimum arrangement trial calculation unit 154 outputs various types of information used for the user of the assistance server 140 to determine an installation plan of the battery replacement apparatuses 130.

In a first embodiment, the user of the assistance server 140 determines a restriction condition of the optimization problem so that the optimum arrangement trial calculation unit 154 determines all the arrangements of the m battery replacement apparatuses 130. For example, the user of the assistance server 140 starts the information processing in the optimum arrangement trial calculation unit 154 without designating the number of battery replacement apparatuses 130 to be arranged in a single area. Note that the user of the assistance server 140 may designate a condition related to the number of battery replacement apparatuses 130 to be arranged in a single area (for example, condition related to upper limit value).

In this case, the optimum arrangement trial calculation unit 154 outputs an optimum solution considering not only a pattern in which a single battery replacement apparatus 130 is arranged in a single area but also a pattern in which a plurality of battery replacement apparatuses 130 are arranged in a single area. Accordingly, the position of each of the m battery replacement apparatuses 130 is determined. Further, the number of battery replacement apparatuses 130 to be arranged in each of the n areas is determined.

In a second embodiment, the user of the assistance server 140 determines a restriction condition of the optimization problem so that the optimum arrangement trial calculation unit 154 determines an arrangement of s battery replacement apparatuses 130 out of the m battery replacement apparatuses 130. Herein, s is an integer which is 1 or more and smaller than m.

For example, the user of the assistance server 140 designates the number of battery replacement apparatuses 130 to be arranged in a single area. In this case, the optimization solver 1124 executes processing for solving the optimization problem under a restriction condition that the number of battery replacement apparatuses 130 to be arranged in a single area is a value designated by the user. For example, when an arrangement pattern for each trial is determined, the optimization solver 1124 determines, after determining an area to arrange the battery replacement apparatuses 130, the number of battery replacement apparatuses 130 to be installed in the area based on a user designation.

Accordingly, the positions of the s battery replacement apparatuses 130 out of the m battery replacement apparatuses 130 are determined. In this step, the number of battery replacement apparatuses 130 to be arranged in each of the n areas is not completely determined. Therefore, the optimum arrangement trial calculation unit 154 may further execute processing for determining an arrangement of the rest of the m-s battery replacement apparatuses 130. For example, processing for allocating the m-s battery replacement apparatuses 130 to an area where the priority described above is high is executed.

Using FIG. 13, an example of the above-described first embodiment will be described. Note that it is apparent from persons skilled in the art who have read the descriptions related to the first embodiment that also in the second embodiment, the positions of the s battery replacement apparatuses 130 can be determined by a similar procedure.

According to the present embodiment, first, in S1420, the optimum arrangement trial calculation unit 154 determines the number of battery replacement apparatuses 130 to be arranged in each candidate site area within a target zone. Further, the optimum arrangement trial calculation unit 154 sets the position and SOC of each of the plurality of vehicles 120 at a particular time (step) in the dynamic data 1142, as an initial position and initial SOC of each of the plurality of vehicles 120.

Next, in S1422, the optimum arrangement trial calculation unit 154 reads data of a next time (step) in the dynamic data 1142. Of the plurality of vehicles 120, the optimum arrangement trial calculation unit 154 extracts a vehicle 120 satisfying a condition predetermined as a replacement condition of the battery 122. The optimum arrangement trial calculation unit 154 determines to replace the battery 122 of the one or more extracted vehicles 120.

More specifically, the optimum arrangement trial calculation unit 154 compares an SOC value of each of the plurality of vehicles 120 at the above-described time and a predetermined numerical range. For example, of the plurality of vehicles 120, the optimum arrangement trial calculation unit 154 extracts a vehicle 120 in which the SOC value thereof is smaller than a lower limit of the above-described numerical range.

Further, of the plurality of vehicles 120, the optimum arrangement trial calculation unit 154 may extract a vehicle 120 in which the SOC value thereof is larger than an upper limit of the above-described numerical range. Of the vehicles 120 that are indicated by the dynamic data 1142 to travel in a zone where the battery replacement apparatus 130 is not arranged and the battery replacement apparatus 130 cannot be added in later steps, the optimum arrangement trial calculation unit 154 may extract a vehicle 120 in which the SOC value thereof is larger than the upper limit of the above-described numerical range.

Next, in S1424, the optimum arrangement trial calculation unit 154 determines a replacement time and replacement place of the battery 122 for each of the one or more extracted vehicles 120. For example, the optimum arrangement trial calculation unit 154 determines, as the replacement place, the battery replacement apparatus 130 arranged at a position closest to the position of each of the one or more extracted vehicles 120. Further, the optimum arrangement trial calculation unit 154 calculates, for each of the one or more extracted vehicles 120, a time required to reach the battery replacement apparatus 130 determined as the replacement place, and determines the time as the replacement time.

As described above, a movement path of each of the one or more extracted vehicles 120 is determined by the dynamic data 1142. Further, the dynamic data 1142 is created under the condition that the replacement of the battery 122 is not to be considered. Therefore, depending on the vehicle 120, it is impossible to move to the battery replacement apparatus 130 determined as the replacement place unless deviating from the movement path indicated by the dynamic data 1142.

Therefore, when there is a need to change the movement path for replacing the battery 122, in S1424, the optimum arrangement trial calculation unit 154 edits the dynamic data 1142 of the vehicle 120 for which the movement path needs to be changed. Specifically, the optimum arrangement trial calculation unit 154 edits the dynamic data 1142 so that the above-described vehicle 120 moves toward the original destination via the battery replacement apparatus 130 determined as the replacement place.

Next, in S1428, the optimum arrangement trial calculation unit 154 calculates an ending time of the replacement work of the battery 122 for each of the one or more extracted vehicles 120. For example, the optimum arrangement trial calculation unit 154 judges whether a replaceable battery 122 is accommodated in the battery replacement apparatus 130 determined as the replacement place, at the replacement time.

When judged that a replaceable battery 122 is accommodated in the battery replacement apparatus 130, the optimum arrangement trial calculation unit 154 calculates the above-described replacement time or a time obtained by adding a predetermined working time to the time, as the ending time of the replacement work of the battery 122. Further, the optimum arrangement trial calculation unit 154 updates the SOC of the battery 122 mounted on the vehicle 120 to the SOC value of the battery 122 used for the replacement (that is, a new battery 122 mounted on the vehicle 120 by the replacement).

On the other hand, when judged that a replaceable battery 122 is not accommodated in the battery replacement apparatus 130, the optimum arrangement trial calculation unit 154 calculates a time at which charging of the battery 122 accommodated in the battery accommodation portion 132 ends. Further, the optimum arrangement trial calculation unit 154 calculates the above-described time at which the charging ends or a time obtained by adding a predetermined working time to the time, as the ending time of the replacement work of the battery 122. Furthermore, the optimum arrangement trial calculation unit 154 updates the SOC of the battery 122 mounted on the vehicle 120 to the SOC value of the battery 122 used for the replacement.

Next, in S1440, the optimum arrangement trial calculation unit 154 repeats the processing of S1422 to S1428 while proceeding the time of S1422 one after another. Accordingly, a solution in such a manner as to satisfy a predetermined condition related to the battery replacement is searched for. Specifically, a solution with which the battery 122 can be replaced within a predetermined numerical range is searched for, with respect to all pieces of dynamic data.

When the above-described solution is found, the optimum arrangement trial calculation unit 154 calculates a value of each item constituting the objective function. As described above, the objective function is determine as, for example, “cost weight×cost variable”+“convenience weight×convenience variable”+“safety weight×safety variable”. The optimum arrangement trial calculation unit 154 calculates a value of each item of the cost variable, a value of each item of the convenience variable, and a value of each item of the safety variable. Further, the optimum arrangement trial calculation unit 154 substitutes the value of each item into the objective function to calculate the objective function. Accordingly, the calculation in which S1420 to S1440 are set as one set ends.

Next, in S1460, the optimum arrangement trial calculation unit 154 repeats the processing of S1420 to S1440 while changing the arrangement condition of the battery replacement apparatus 130 in S1420. Examples of the arrangement condition of the battery replacement apparatus 130 include a condition related to an upper limit of the number of battery replacement apparatuses 130 to be arranged, a condition related to an upper limit of an installation cost of the battery replacement apparatuses 130, and the like.

Upon executing the processing of S1420 to S1440 for all combinations satisfying the arrangement condition of the battery replacement apparatuses 130, the optimum arrangement trial calculation unit 154 ends the processing of repeating S1420 to S1440. Further, the optimum arrangement trial calculation unit 154 compares the plurality of objective functions obtained by repeatedly executing S1420 to S1440, and specifies a calculation in which the objective function becomes minimum out of the plurality of calculations that have been executed repeatedly.

The optimum arrangement trial calculation unit 154 references a calculation result of the calculation in which the objective function becomes minimum and searches for (i) a combination of the installation locations of the battery replacement apparatuses 130 determined in S1420 in the calculation and (i) a combination of the replacement places of the batteries 122 determined in S1424 in the calculation. The optimum arrangement trial calculation unit 154 may output the combination of the installation locations of the battery replacement apparatuses 130 obtained by the above-described search, as a trial calculation result regarding the arrangement of the battery replacement apparatuses 130. The optimum arrangement trial calculation unit 154 may also output the combination of the replacement places of the batteries 122 obtained by the above-described search, as an evaluation material for an optimum arrangement. The optimum arrangement trial calculation unit 154 may also output the combination of the replacement places of the batteries 122 obtained by the above-described search, as an evaluation material for an optimum arrangement not set as the objective function. Accordingly, for example, a circulation state of the battery 122 in a market, a user bias, and the like can be evaluated.

The optimum solution output by the optimization solver 1124 of the optimum arrangement trial calculation unit 154 may be an example of the first output amount. The optimum solution data 1144 may be an example of the first output amount. The various types of information used by the user of the assistance server 140 to determine the installation plan of the battery replacement apparatuses 130 may be an example of the second output amount.

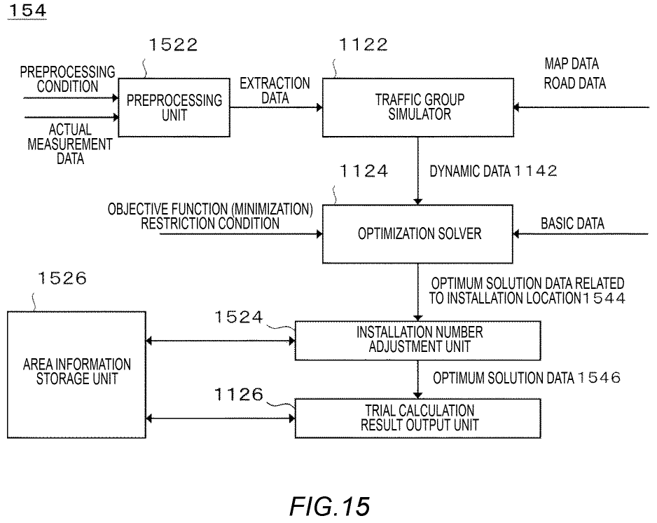

FIG. 15 schematically shows another example of the internal configuration of the optimum arrangement trial calculation unit 154. In the present embodiment, the optimum arrangement trial calculation unit 154 includes a preprocessing unit 1522, the traffic group simulator 1122, the optimization solver 1124, an installation number adjustment unit 1524, the trial calculation result output unit 1126, and an area information storage unit 1526. The optimum arrangement trial calculation unit 154 described in relation to FIG. 15 may have a configuration similar to that of the optimum arrangement trial calculation unit 154 described in relation to FIGS. 11 to 14 except for the point of including the preprocessing unit 1522, the installation number adjustment unit 1524, and the area information storage unit 1526.

According to the present embodiment, for example, when m battery replacement apparatuses 130 are installed in a target zone divided into n areas, the optimum arrangement trial calculation unit 154 determines the arrangement of s battery replacement apparatuses 130 out of the m battery replacement apparatuses 130. Further, the installation number adjustment unit 1524 determines the arrangement of the rest of the m-s battery replacement apparatuses 130. Herein, n and m are positive integers, and s is an integer which is 1 or more and smaller than m.

In the present embodiment, the preprocessing unit 1522 acquires actual measurement data related to a movement history of one or more vehicles, and extracts data (may be referred to as extraction data) that matches a preprocessing condition designated by the user of the assistance server 140, for example, out of the actual measurement data. Examples of the preprocessing condition include (i) a condition that a length of a staying time inside a target zone in a unit period or a particular period is equal to or larger than a predetermined value, (ii) a condition that a movement distance inside a target zone in a unit period or a particular period is equal to or larger than a predetermined value, (iii) a condition that an average value of movement distances per unit period falls within a predetermined numerical range, and the like.

The preprocessing unit 1522 outputs the extraction data to the traffic group simulator 1122. Accordingly, unnecessary noises are removed.

In the present embodiment, the traffic group simulator 1122 simulates a movement of the passenger 22 or the vehicle 120 in a target zone based on the extraction data acquired from the preprocessing unit 1522. The traffic group simulator 1122 may also simulate a movement of the passenger 22 or the vehicle 120 in a target zone based on the extraction data acquired from the preprocessing unit 1522 and prediction data.

In the present embodiment, the traffic group simulator 1122 may edit a start point and/or end point of data that passes through a target zone out of the extraction data acquired from the preprocessing unit 1522. In one embodiment, the traffic group simulator 1122 overwrites a position of a target zone from which the vehicle 120 has entered from outside, by a departure point of the vehicle 120. In another embodiment, the traffic group simulator 1122 overwrites a position of a target zone from which the vehicle 120 has moved out of the target zone, by a destination of the vehicle 120.

In the present embodiment, the optimization solver 1124 operates in a manner similar to that of the second embodiment described in relation to FIG. 14. Further, as described in relation to FIG. 11, the optimization solver 1124 is configured to be capable of outputting at least one of the first output amount and the second output amount.

As described above, the optimization solver 1124 of the optimum arrangement trial calculation unit 154 outputs a solution to an optimization problem for installing the m battery replacement apparatuses 130 in the target zone divided into n areas. In the present embodiment, the optimization solver 1124 determines the arrangement of s battery replacement apparatuses 130 out of the m battery replacement apparatuses 130. The optimization solver 1124 outputs optimum solution data 1544 related to installation positions of the s battery replacement apparatuses 130. The optimization solver 1124 will be described later in detail.

In the present embodiment, the installation number adjustment unit 1524 determines the arrangement of the rest of the m-s battery replacement apparatuses 130. For example, the installation number adjustment unit 1524 executes processing for allocating the rest of the m-s battery replacement apparatuses 130 to an area where the priority described above is high out of the areas where the s battery replacement apparatuses 130 are to be arranged. In one embodiment, the installation number adjustment unit 1524 allocates a predetermined number of battery replacement apparatuses 130 in order from higher priority. At a time point the m-s battery replacement apparatuses 130 are allocated, the installation number adjustment unit 1524 ends the allocation processing. In another embodiment, the installation number adjustment unit 1524 allocates the battery replacement apparatuses 130 in a number corresponding to a value of the priority of each area, to at least a part of the areas where the s battery replacement apparatuses 130 are to be arranged.

Accordingly, the position of each of the m battery replacement apparatuses 130 is determined. Further, the number of battery replacement apparatuses 130 to be arranged in each of the n areas is determined. The installation number adjustment unit 1524 outputs optimum solution data 1546 indicating the position of each of the m battery replacement apparatuses 130 and/or the number of battery replacement apparatuses 130 to be arranged in each of the n areas. An example of the information indicating the position of each of the m battery replacement apparatuses 130 and/or the number of battery replacement apparatuses 130 to be arranged in each of the n areas is the various types of information described above indicating the arrangement patterns.

The installation number adjustment unit 1524 may output a calculation result related to each arrangement pattern. Examples of the above-described calculation result include (i) a value of an objective function in each arrangement pattern, (ii) a value of at least one of the first relational expression, the second relational expression, and the third relational expression included in the objective function, (iii) a value of a part of terms included in at least one of the first relational expression, the second relational expression, and the third relational expression, and the like.

In the present embodiment, the trial calculation result output unit 1126 outputs a trial calculation result. For example, the trial calculation result output unit 1126 outputs a trial calculation result based on information output by the installation number adjustment unit 1524. The trial calculation result output unit 1126 may generate a trial calculation result based on the information output by the installation number adjustment unit 1524 and information related to each area, that is stored in the area information storage unit 1526. The trial calculation result will be described later in detail.

In the present embodiment, the area information storage unit 1526 stores various types of information related to each of the one or more areas. For example, the area information storage unit 1526 stores information indicating a geographic reach of each of the one or more areas. Examples of the information indicating a geographic reach of each area include a plurality of positional coordinates for specifying a range of each area, and the like. For example, the area information storage unit 1526 stores information related to a representative facility provided inside each of the one or more areas. The number of representative facilities included in a single area may be one, or may be plural.

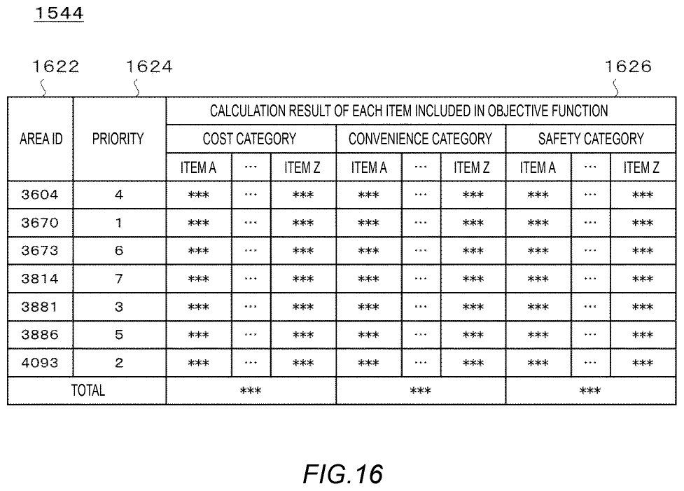

FIG. 16 schematically shows an example of a data structure of the optimum solution data 1544. In the present embodiment, an example of the data structure of the optimum solution data 1544 will be described while taking a case where m is 8, s is 7, and the number of battery replacement apparatuses 130 installable in a single area is one, as an example. That is, in the present embodiment, the optimum arrangement trial calculation unit 154 extracts seven areas where seven battery replacement apparatuses 130 are respectively installed out of n areas. Further, in the present embodiment, for simplifying descriptions, an example of the data structure of the optimum solution data 1544 will be described while taking a case where the optimization solver 1124 outputs a single optimum solution in which a value of an objective function becomes minimum out of nCs arrangement patterns, as an example.

In the present embodiment, each record of the optimum solution data 1544 stores, for example, an area ID 1622 of an area where the battery replacement apparatus 130 is installed, information 1624 indicating priority of the area, and information 1626 indicating a calculation result of each item included in the objective function, in association with one another. An example of the items included in the objective function is a plurality of items described in relation to FIG. 13. The information 1626 may include a total value of items included in each of the plurality of categories described in relation to FIG. 13. The information 1626 may include at least one of a value of the first relational expression, a value of the second relational expression, and a value of the third relational expression in each trial. The value of the first relational expression may be a total value of values of a first function expression in each step in each area in each trial. The value of the second relational expression may be a total value of values of a second function expression in each step in each area in each trial. The value of the third relational expression may be a total value of values of a third function expression in each step in each area in each trial. The optimum solution data 1544 may include information indicating a total value of the objective functions. Note that in the present embodiment, the priority of an area indicates that, as a value of the priority increases, the area is to be prioritized more or more importance is to be placed on the area.

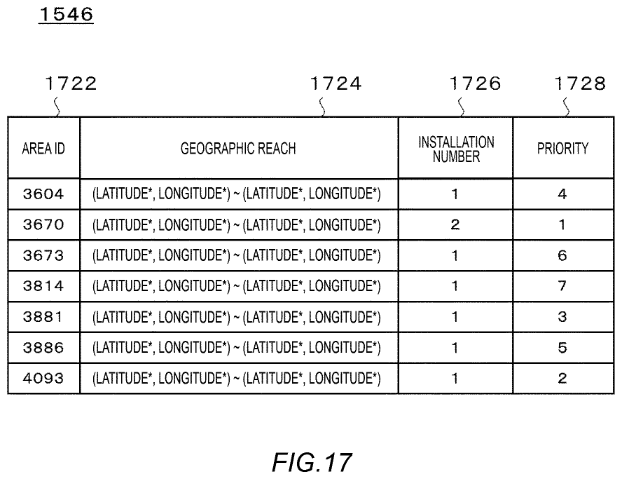

FIG. 17 schematically shows an example of a data structure of the optimum solution data 1546. In the present embodiment, an example of the data structure of the optimum solution data 1546 will be described while taking a case where the installation number adjustment unit 1524 determines an area to install the remaining one battery replacement apparatus 130 based on the optimum solution data 1544 described in relation to FIG. 16, as an example.

In the present embodiment, each record of the optimum solution data 1546 stores, for example, an area ID 1722 of an area where the battery replacement apparatus 130 is to be installed, information 1724 indicating a geographic reach of the area, information 1726 indicating the number of battery replacement apparatuses 130 to be installed in the area, and information 1728 indicating priority of the area, in association with one another. For example, the trial calculation result output unit 1126 references the area information storage unit 1526 to acquire the information 1724 indicating the geographic reach of each area.

In the present embodiment, the trial calculation result output unit 1126 first compares priority of each area. Next, the trial calculation result output unit 1126 increases the installation number of the area with highest priority by one.

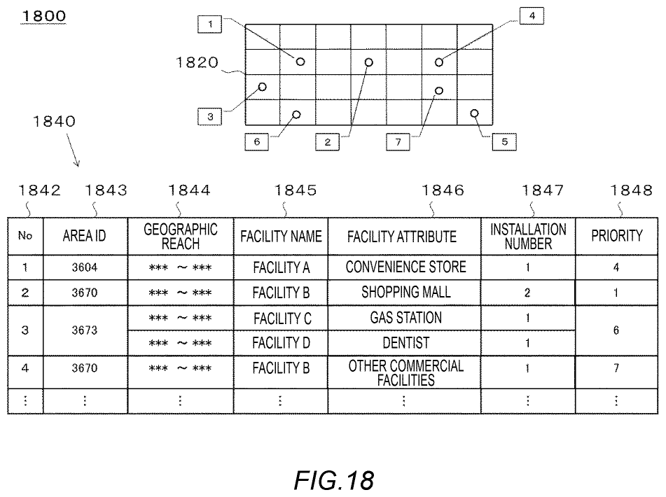

FIG. 18 schematically shows an example of an output result 1800 of the trial calculation result output unit 1126. In the present embodiment, the output result 1800 includes a map 1820 that presents geographic positions of the installation positions of the battery replacement apparatuses 130 and a list 1840 that presents information of representative facilities provided in the areas where the battery replacement apparatuses 130 are installed. The above-described representative facilities may be a candidate site point of an installation location of the battery replacement apparatus 130.

For example, the map 1820 includes a map image of a target zone, an icon or object indicating a position of one or more battery replacement apparatuses 130, and an icon or object indicating identification information of the one or more battery replacement apparatuses 130. For example, the list 1840 includes a number 1842 allocated to each of the one or more battery replacement apparatuses 130, an area ID 1843 of an area where each of the one or more battery replacement apparatuses 130 is installed, information 1844 indicating a geographic reach of each area, identification information 1845 of a representative facility of each area, information 1846 indicating an attribute of each facility, information 1847 indicating the number of battery replacement apparatuses 130 to be installed in each area, and information 1848 indicating priority of each area. The identification information of the representative facility may be a name of the facility.

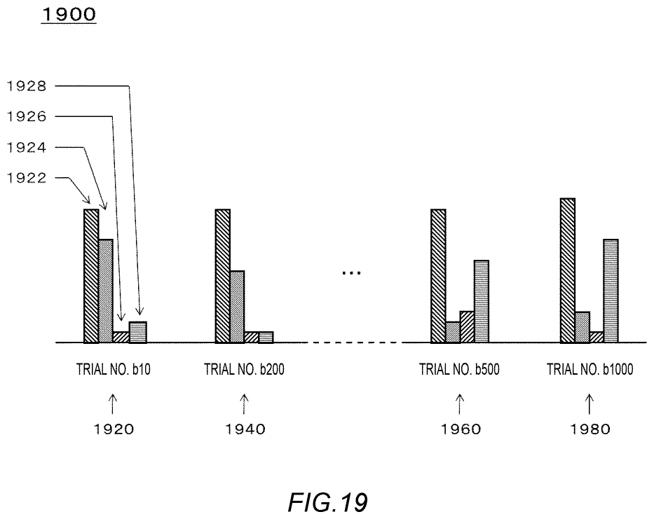

FIG. 19 schematically shows an example of an output result 1900 of the trial calculation result output unit 1126. In the present embodiment, the output result 1900 indicates a calculation result of each of a plurality of trials. For example, the output result 1900 includes an icon or object indicating each of a calculation result 1920 of a trial number b10, a calculation result 1940 of a trial number b200, a calculation result 1960 of a trial number b500, and a calculation result 1980 of a trial number b1000. For example, the output result 1900 includes, as the icon or object indicating the calculation result in each trial, a graph, an icon, or an object indicating each of a value 1922 of the objective function, a value 1924 of the first relational expression, a value 1926 of the second relational expression, and a value 1928 of the third relational expression. The output result 1900 and the calculation result in each trial are used for determining the positions at which the battery replacement apparatuses 130 are to be arranged, for example. For example, a human or a computer references these results to determine the arrangement of the battery replacement apparatus 130 based on a calculation result of a particular trial out of the plurality of trials included in the output result 1900. The output result 1900 and the calculation result in each trial may be an example of the second output amount.

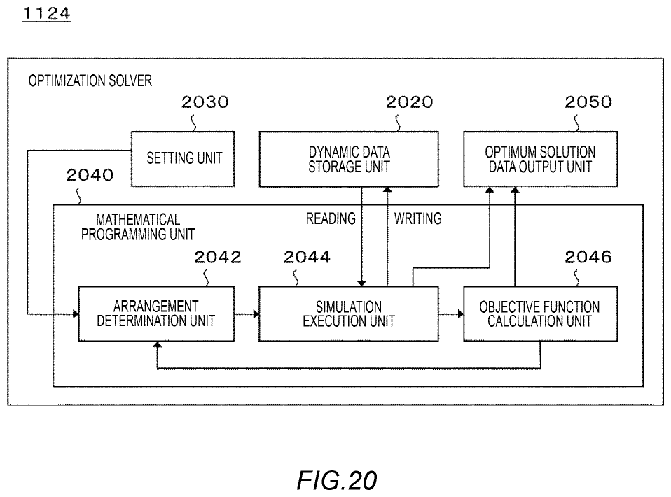

FIG. 20 schematically shows an example of an internal configuration of the optimization solver 1124. In the present embodiment, the optimization solver 1124 includes a dynamic data storage unit 2020, a setting unit 2030, a mathematical programming unit 2040, and an optimum solution data output unit 2050. In the present embodiment, the mathematical programming unit 2040 includes an arrangement determination unit 2042, a simulation execution unit 2044, and an objective function calculation unit 2046.

In the present embodiment, the dynamic data storage unit 2020 stores dynamic data 1142 output by the traffic group simulator 1122. The dynamic data storage unit 2020 may output requested dynamic data according to a request from the simulation execution unit 2044. Further, the dynamic data storage unit 2020 may update requested dynamic data according to a request from the simulation execution unit 2044.

In the present embodiment, the setting unit 2030 sets a mathematical programming problem. For example, the setting unit 2030 sets an objective function, a setting condition of the objective function, and a restriction condition. For example, the setting unit 2030 sets a mathematical programming problem based on an instruction from a user. Further, the setting unit 2030 sets each of a plurality of arrangement patterns for which an objective function is to be calculated. The setting unit 2030 outputs information related to the above-described various settings to the mathematical programming unit 2040.

In the present embodiment, the mathematical programming unit 2040 executes processing for solving the mathematical programming problem. The mathematical programming unit 2040 solves the mathematical programming problem by repeating processing of the arrangement determination unit 2042, the simulation execution unit 2044, and the objective function calculation unit 2046.

For example, first, the arrangement determination unit 2042 determines one of a plurality of arrangement patterns set by the setting unit 2030, as an arrangement pattern to be solved in a current trial. Next, using the arrangement pattern determined by the arrangement determination unit 2042 and dynamic data of one or more vehicles 120 stored in the dynamic data storage unit 2020, the simulation execution unit 2044 performs a simulation of dynamics of the one or more vehicles 120 during a target period. Further, the objective function calculation unit 2046 calculates a value of the objective function during the target period.

Upon completing the simulation of the dynamics of the one or more vehicles 120 during the target period, the arrangement determination unit 2042 determines an arrangement pattern to be solved in the next trial, and the above-described processing is repeated. Upon obtaining simulation results related to all the arrangement patterns set by the setting unit 2030, the mathematical programming unit 2040 ends the processing.

In the present embodiment, the optimum solution data output unit 2050 acquires the calculation result of the mathematical programming unit 2040. The optimum solution data output unit 2050 determines one or more arrangement patterns to become a solution to the set mathematical programming problem, based on the value of the objective function of each of the plurality of arrangement patterns set by the setting unit 2030.

The optimum solution data output unit 2050 may calculate priority of each of the one or more battery replacement apparatuses 130 in each of the above-described one or more arrangement patterns. The optimum solution data output unit 2050 generates optimum solution data based on these pieces of data. Examples of the optimum solution data include the optimum solution data 1144 and the optimum solution data 1544 described above, and the like.

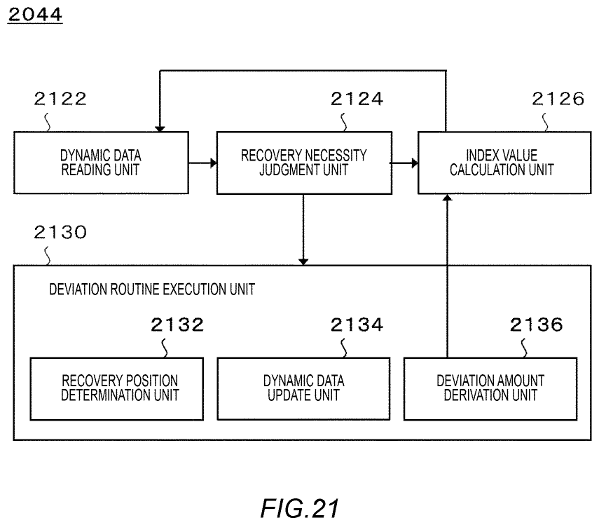

FIG. 21 schematically shows an example of an internal configuration of the simulation execution unit 2044. In the present embodiment, the simulation execution unit 2044 includes a dynamic data reading unit 2122, a recovery necessity judgment unit 2124, an index value calculation unit 2126, and a deviation routine execution unit 2130. In the present embodiment, the deviation routine execution unit 2130 includes a recovery position determination unit 2132, a dynamic data update unit 2134, and a deviation amount derivation unit 2136.

As described above, the simulation execution unit 2044 performs a simulation of dynamics of the one or more vehicles 120 during the target period in the arrangement pattern determined by the arrangement determination unit 2042. Accordingly, replacement of the battery 122 in the one or more battery replacement apparatuses 130 indicated by the above-described arrangement pattern, is simulated.

As described above, the dynamic data 1142 stores, for each of p vehicles 120, a position and SOC in each of q steps. Further, the dynamic data 1142 stores, for each of the p vehicles 120, a status of the vehicle 120 in each of the q steps. Herein, p and q are positive integers. When the vehicle 120 is a service vehicle, the simulation execution unit 2044 can analyze the above-described status to judge whether the vehicle 120 is executing the service or whether the service of the vehicle 120 has ended, or the like.

According to the present embodiment, the simulation execution unit 2044 reads the data of the q steps in order to proceed with the simulation. In each step, the simulation execution unit 2044 judges whether replacement demand has arisen based on the SOC of each vehicle in each step. When the replacement demand has arisen, the simulation execution unit 2044 newly generates dynamic data of the above-described vehicle 120 so that the vehicle 120 for which the battery 122 is to be replaced moves to the nearest battery replacement apparatus 130. The simulation execution unit 2044 updates the dynamic data stored in the dynamic data storage unit 2020 by the new dynamic data. Further, after ending the simulation, the simulation execution unit 2044 calculates the objective function and various index values required for deriving the various KPIs described above. Upon ending the above-described processing for all of the q steps, the simulation execution unit 2044 ends the simulation related to the current arrangement pattern.

In the present embodiment, the dynamic data reading unit 2122 accesses the dynamic data storage unit 2020 and reads the data of the q steps in order. For example, the dynamic data reading unit 2122 reads data of an i-th step and outputs information indicating the position and SOC of each of the p vehicles 120 in the step to the recovery necessity judgment unit 2124. The dynamic data reading unit 2122 may also output information indicating a status of each of the p vehicles 120 to the recovery necessity judgment unit 2124. Herein, i is a positive integer.

In the present embodiment, the recovery necessity judgment unit 2124 judges whether energy recovery is necessary. Specifically, the recovery necessity judgment unit 2124 acquires information indicating the position and SOC of each of the p vehicles 120 in the i-th step. Based on the SOC of each of the p vehicles 120, the recovery necessity judgment unit 2124 judges whether replacement of the battery 122 is necessary in each of the p vehicles 120.

When judged that the replacement of the battery 122 is unnecessary for a particular vehicle 120, the recovery necessity judgment unit 2124 outputs information indicating the position and SOC of each of the p vehicles 120 in the i-th step, to the index value calculation unit 2126. The recovery necessity judgment unit 2124 may also output information indicating a status of each of the p vehicles 120 to the index value calculation unit 2126.

When judged that the replacement of the battery 122 is necessary for a particular vehicle 120, the recovery necessity judgment unit 2124 outputs, to the deviation routine execution unit 2130, a signal for causing the deviation routine execution unit 2130 to start processing for generating new dynamic data of the above-described particular vehicle 120. Further, the recovery necessity judgment unit 2124 outputs information indicating the position and SOC of each of the p vehicles 120 in the i-th step, to the index value calculation unit 2126. The recovery necessity judgment unit 2124 may also output information indicating a status of each of the p vehicles 120 to the index value calculation unit 2126.

In the present embodiment, the index value calculation unit 2126 calculates various indices. For example, the index value calculation unit 2126 calculates a value of each item of the objective function. An example of each item of the objective function is at least one of the first relational expression, the second relational expression, and the third relational expression. Each item of the objective function may alternatively be a part of terms of at least one of the first relational expression, the second relational expression, and the third relational expression. The index value calculation unit 2126 may also calculate an accumulated value of the number of times the battery replacement apparatus 130 is used. Accordingly, when completing the processing on all pieces of data of the q steps, the objective function calculation unit 2046 can calculate the value of the objective function.

In the present embodiment, the deviation routine execution unit 2130 executes, for a particular vehicle 120 that has been judged that the replacement of the battery 122 is necessary, processing for performing a simulation of a state where the particular vehicle 120 deviates from the original movement path indicated by the dynamic data to move to a position of a particular battery replacement apparatus 130. According to the present embodiment, by the deviation routine execution unit 2130 overwriting the dynamic data of the above-described particular vehicle 120, the above-described deviation state can be simulated.

In the present embodiment, the recovery position determination unit 2132 determines the battery replacement apparatus 130 to replace the battery 122 of the above-described particular vehicle 120. For example, the recovery position determination unit 2132 determines the above-described battery replacement apparatus 130 so that it matches the condition set by the setting unit 2030. Examples of the condition set by the setting unit 2030 include a condition that it is a battery replacement apparatus 130 arranged at a position closest to a position at which the replacement of the battery 122 has been judged as necessary, a condition that it is a battery replacement apparatus 130 capable of accommodating most batteries 122 out of the one or more battery replacement apparatuses 130 arranged within a predetermined distance from a position at which the replacement of the battery 122 has been judged as necessary, and the like.

In the present embodiment, the dynamic data update unit 2134 determines a movement path from the position at which the replacement of the battery 122 has been judged as necessary to a position of the battery replacement apparatus 130 determined by the recovery position determination unit 2132. The dynamic data update unit 2134 generates new dynamic data based on a statistical value such as a movement speed (km/hr), electricity consumption (Ah/kg), or the like and the above-described movement path. Further, the dynamic data update unit 2134 updates the dynamic data of the above-described particular 120, that is stored in the dynamic data storage unit 2020, by the above-described new dynamic data.

Further, when there are no lendable batteries 122 in the battery replacement apparatus 130 at a time point the vehicle 120 arrives at the position of the battery replacement apparatus 130, the dynamic data update unit 2134 may determine a behavior of the vehicle 120 or the passenger 22 so that it matches the condition set by the setting unit 2030. Examples of the condition set by the setting unit 2030 include (i) a condition that the battery replacement apparatus 130 is to be determined again by the recovery position determination unit 2132, (ii) a condition that the battery replacement apparatus 130 is to be determined again by the recovery position determination unit 2132 until the number of times of reselecting the battery replacement apparatus 130 reaches a predetermined value, and to stand by until the battery 122 becomes lendable when the number of times of reselecting the battery replacement apparatus 130 exceeds the predetermined value, and the like.

Note that as described above, when the vehicle 120 is a service vehicle used in a service of transportation, logistics, or the like, the passenger 22 of the vehicle 120 (for example, driver) may not be able to replace the battery 122 until ending the service even when a remaining capacity of the battery 122 becomes smaller than a predetermined value while the service is in operation. Whether the vehicle 120 is executing the service can be determined based on information stored in the status 1230 of the dynamic data 1142, for example.

For example, when the vehicle 120 that has been judged that the replacement of the battery 122 is necessary is executing the service, the dynamic data update unit 2134 overwrites dynamic data of the above-described particular vehicle 120 based on (i) an assumption that the vehicle 120 will move from a departure point S1 to a destination G1 by traveling on a path scheduled at departure and (ii) an assumption that the vehicle 120 will move from the destination G1 to the battery replacement apparatus 130 nearest to the position at which the replacement demand has arisen. As described above, when the replacement distance is larger than the remaining traveling distance of the vehicle 120, the vehicle 120 cannot replace the battery 122 using the battery replacement apparatus 130 nearest to the position at which the replacement demand has arisen. Therefore, the dynamic data update unit 2134 overwrites the status of the vehicle 120 from a status indicating that the vehicle 120 is executing the service to a status indicating that the vehicle 120 is out of service. Further, the dynamic data of the vehicle 120 is overwritten so that the vehicle 120 moves from the departure point toward the battery replacement apparatus 130 nearest to the departure point or the battery replacement apparatus 130 nearest to the position at which the replacement demand has arisen.

In the present embodiment, the deviation amount derivation unit 2136 derives various deviation amounts accompanying the movement of the above-described particular vehicle 120 to a position of a particular battery replacement apparatus 130 while deviating from an original movement path. The deviation amount derivation unit 2136 may derive the various deviation amounts by a procedure similar to the deviation amount estimation procedure or derivation procedure in the recovery demand estimation unit 148, the deviation amount estimation unit 832, or the deviation amount derivation unit 936. As described above, examples of the deviation amount include a time, distance, energy, cost, and the like.

Further, as described in relation to the deviation amount estimation unit 832 and/or the evaluation unit 834, the deviation amount calculation procedure may differ between a case where the vehicle 120 is executing a service and a case where the vehicle 120 is out of service. Whether the vehicle 120 is executing a service can be determined based on information stored in the status 1230 of the dynamic data 1142, for example. A type of deviation amount to be derived by the deviation amount derivation unit 2136 is determined by the setting unit 2030, for example. The deviation amount derivation unit 2136 may derive an evaluation value of each demand arising position by a procedure similar to that of the evaluation unit 834.

The replacement of the battery 122 may be an example of the recovery of energy. The position of a particular battery replacement apparatus 130 may be an example of the recovery position.

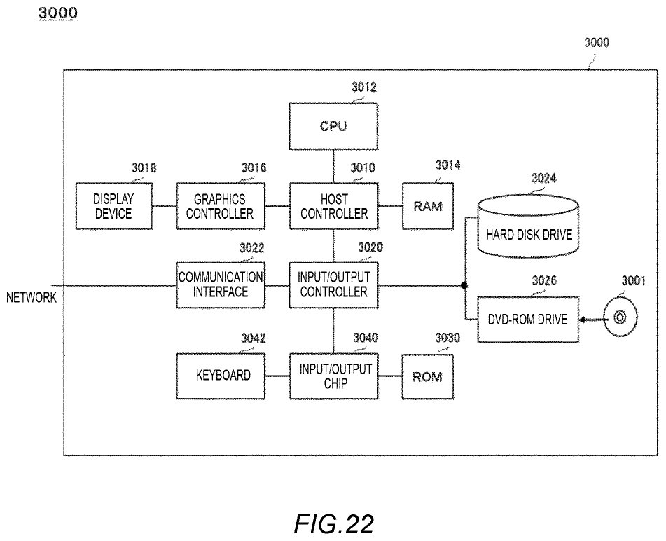

FIG. 22 shows an example of a computer 3000 in which a plurality of aspects of the present invention may be embodied entirely or partially. For example, the assistance server 140 is realized by the computer 3000. A part of the assistance server 140 may be realized by the computer 3000.

A program that is installed in the computer 3000 can cause the computer 3000 to perform an operation associated with an apparatus according to the embodiment of the present invention or to function as one or more “units” of the apparatus, or cause the computer 3000 to perform the operation or the one or more units thereof, and/or cause the computer 3000 to perform processes of the embodiment of the present invention or steps thereof. Such a program may be executed by a CPU 3012 to cause the computer 3000 to perform particular operations associated with some or all of the blocks of flowcharts and block diagrams described in the present specification.

The computer 3000 according to the present embodiment includes the CPU 3012, a RAM 3014, a GPU 3016, and a display device 3018, which are mutually connected by a host controller 3010. The computer 3000 also includes input/output units such as a communication interface 3022, a hard disk drive 3024, a DVD-ROM drive 3026, and an IC card drive, which are connected to the host controller 3010 via an input/output controller 3020. The computer also includes legacy input/output units such as a ROM 3030 and a keyboard 3042, which are connected to the input/output controller 3020 through an input/output chip 3040.

The CPU 3012 operates according to programs stored in the ROM 3030 and the RAM 3014, thereby controlling each unit. The GPU 3016 acquires image data generated by the CPU 3012 in a frame buffer or the like provided in the RAM 3014 or in itself, so that the image data is displayed on the display device 3018.

The communication interface 3022 communicates with other electronic devices via a network. The hard disk drive 3024 stores the program and data to be used by the CPU 3012 in the computer 3000. The DVD-ROM drive 3026 reads a program or data from the DVD-ROM 3001, and provides the program or data to the hard disk drive 3024 via the RAM 3014. The IC card drive reads the program and data from an IC card, and/or writes the program and data to the IC card.

The ROM 3030 stores therein a boot program or the like that is performed by the computer 3000 at the time of activation, and/or a program depending on the hardware of the computer 3000. The input/output chip 3040 may also connect various input/output units to the input/output controller 3020 via a parallel port, a serial port, a keyboard port, a mouse port, or the like.

A program is provided by a computer-readable storage medium, such as the DVD-ROM 3001 or the IC card. The program is read from the computer-readable storage medium, installed into the hard disk drive 3024, RAM 3014, or ROM 3030, which are also examples of the computer-readable storage medium, and performed by the CPU 3012. The information processing written in these programs is read into the computer 3000, resulting in cooperation between a program and the above-described various types of hardware resources. An apparatus or method may be configured by realizing an operation or processing of information pursuant to the use of the computer 3000.

For example, when communication is performed between the computer 3000 and an external device, the CPU 3012 may execute a communication program loaded in the RAM 3014 and instruct the communication interface 3022 to perform communication processing based on processing written in the communication program. Under the control of the CPU 3012, the communication interface 3022 reads transmission data stored in a transmission buffer area provided in a recording medium such as the RAM 3014, the hard disk drive 3024, the DVD-ROM 3001, or the IC card, and transmits the read transmission data to the network, or writes reception data received from the network in a reception buffer area or the like provided on the recording medium.

In addition, the CPU 3012 may cause all or a necessary portion of a file or a database to be read into the RAM 3014, the file or the database having been stored in an external recording medium such as the hard disk drive 3024, the DVD-ROM drive 3026 (DVD-ROM 3001), the IC card, and the like, and execute various types of processing on the data on the RAM 3014. Next, the CPU 3012 may write back the processed data into an external recording medium.

Various types of information, such as various types of programs, data, tables, and databases, may be stored in the recording medium to undergo information processing. The CPU 3012 may execute, against the data read from the RAM 3014, various types of processing, including various types of operations designated by an instruction sequence of a program, which are described throughout this disclosure, information processing, a condition judgment, a conditional branch, an unconditional branch, information search/replacement, and the like, and write back the result to the RAM 3014. In addition, the CPU 3012 may search for information in a file, a database, or the like, in the recording medium. For example, when a plurality of entries, each having an attribute value of a first attribute associated with an attribute value of a second attribute, are stored in the recording medium, the CPU 3012 may search for an entry whose attribute value of the first attribute matches a designated condition, from among the plurality of entries, and read the attribute value of the second attribute stored in the entry, thereby acquiring the attribute value of the second attribute associated with the first attribute satisfying the predetermined condition.

The above-described program or software modules may be stored in the computer-readable storage medium on or near the computer 3000. Furthermore, a recording medium such as a hard disk or a RAM provided within a server system connected to a dedicated communication network or the Internet can be used as a computer-readable storage medium, to thereby provide the above-described program to the computer 3000 via the network.

While the embodiments of the present invention have been described, the technical scope of the invention is not limited to the above described embodiments. It is apparent to persons skilled in the art that various alterations and improvements can be added to the above-described embodiments. Further, to the extent that there is no technical contradiction, the matters described in the specific embodiment can be applied to other embodiments. It is also apparent from the scope of the claims that the embodiments added with such alterations or improvements can be included in the technical scope of the invention.

The operations, procedures, steps, and stages of each processing performed by an apparatus, system, program, and method shown in the claims, embodiments, or diagrams can be performed in any order as long as the order is not indicated by “prior to,” “before,” or the like and as long as the output from a previous processing is not used in a later processing. Even if the process flow is described using phrases such as “first” or “next” in the claims, embodiments, or diagrams, it does not necessarily mean that the process must be performed in this order.

For example, the following matters are disclosed in the present specification.

(Item A-1)

An estimation apparatus configured to estimate energy recovery demand of an energy accumulation apparatus, including:
an energy amount acquisition unit configured to acquire a remaining energy amount of the energy accumulation apparatus; and
a demand arising position estimation unit configured to estimate a demand arising position which is a position at which the energy recovery demand has arisen, based on a low remaining amount position which is a position of the energy accumulation apparatus when the remaining energy amount of the energy accumulation apparatus acquired by the energy amount acquisition unit becomes equal to or smaller than a predetermined amount.

(Item A-2)

The estimation apparatus according to item A-1, further including:
an arrangement determination unit configured to determine an arrangement of an energy recovery apparatus capable of recovering an accumulated energy amount of the energy accumulation apparatus,
wherein the arrangement determination unit is configured to determine the position at which the energy recovery apparatus is to be arranged based on the demand arising position estimated by the demand arising position estimation unit.

(Item A-3)

The estimation apparatus according to item A-2, wherein
the arrangement determination unit is configured to determine, further based on a position of an existing energy recovery apparatus that has already been arranged,
the position at which the energy recovery apparatus is to be arranged.

(Item A-4)

The estimation apparatus according to any one of items A-1 to A-3, further including:
a deviation amount estimation unit configured to estimate a deviation amount which is a physical amount due to a moving person or a movable body stopping by at a stop-by position based on: (i) a destination location which is a location of a destination of the moving person or movable body which moves while consuming energy of the energy accumulation apparatus; and (ii) the stop-by position which is a position of the energy recovery apparatus capable of recovering the accumulated energy amount of the energy accumulation apparatus and which is a position at which the moving person or the movable body has stopped by in a movement to the destination.

(Item A-5)

The estimation apparatus according to item A-4, wherein
the deviation amount estimation unit is configured to:
estimate the deviation amount based on: (i) a reference amount determined based on the demand arising position and the destination location; and (ii) a stop-by amount determined based on the demand arising position, the stop-by position, and the destination location.

(Item A-6)

The estimation apparatus according to item A-4 or A-5, wherein
the deviation amount estimation unit includes:
a first path determination unit configured to determine, based on the demand arising position and the destination location, a first path used by the moving person or the movable body to move from the demand arising position to the destination location;
a second path determination unit configured to determine, based on the demand arising position, the stop-by position, and the destination location, a second path used by the moving person or the movable body to move from the demand arising position to the destination location via the stop-by position; and
a deviation amount derivation unit configured to derive an estimated value of the deviation amount based on a difference between the physical amount for the moving person or the movable body to move on the second path and the physical amount for the moving person or the movable body to move on the first path.

(Item A-7)

The estimation apparatus according to any one of items A-4 to A-6, wherein
the physical amount is at least one of a distance, a time, and energy.

(Item A-8)

The estimation apparatus according to any one of items A-4 to A-7, further including:
an evaluation unit configured to derive an evaluation value of the demand arising position based on the deviation amount estimated by the deviation amount estimation unit.

(Item A-9)

The estimation apparatus according to item A-8, wherein
the demand arising position estimation unit is configured to estimate one or more demand arising positions for each of one or more of the energy accumulation apparatuses,
the deviation amount estimation unit is configured to estimate the deviation amount for each of the one or more demand arising positions related to each of the one or more energy accumulation apparatuses, and
the evaluation unit is configured to derive the evaluation value for each of the one or more demand arising positions related to each of the one or more energy accumulation apparatuses.

(Item A-10)

The estimation apparatus according to item A-9, wherein
the evaluation unit is configured to derive, based on an evaluation value of the one or more demand arising positions arranged inside each of a plurality of divisions including a predetermined geographic reach, an evaluation value of each of the divisions.

(Item A-11)

The estimation apparatus according to item A-10, further including:
an arrangement determination unit configured to determine the arrangement of the energy recovery apparatus capable of recovering the accumulated energy amount of the energy accumulation apparatus,
wherein the arrangement determination unit is configured to determine the position at which the energy recovery apparatus is to be arranged based on the evaluation value of each of the divisions derived by the evaluation unit.

(Item A-12)

The estimation apparatus according to any one of items A-1 to A-11, further including:
a demand output unit configured to output information for displaying the energy recovery demand on a map.

(Item A-13)

The estimation apparatus according to any one of items A-1 to A-12, further including:
a position acquisition unit configured to acquire a position of the energy accumulation apparatus,
wherein
the energy amount acquisition unit is configured to acquire the remaining energy amount of the energy accumulation apparatus at the position acquired by the position acquisition unit, and
the demand arising position estimation unit is configured to
determine the low remaining amount position based on the position of the energy accumulation apparatus acquired by the position acquisition unit and the remaining energy amount of the energy accumulation apparatus acquired by the energy amount acquisition unit.

(Item A-14)

The estimation apparatus according to item A-13, wherein
the position acquisition unit is configured to acquire a position of the moving person or the movable body which moves while consuming energy of the energy accumulation apparatus, as the position of the energy accumulation apparatus.

(Item A-15)

An estimation method for estimating energy recovery demand of an energy accumulation apparatus, including:
acquiring an energy amount by acquiring a remaining energy amount of the energy accumulation apparatus; and
estimating a demand arising position which is a position at which the energy recovery demand has arisen, based on a low remaining amount position which is a position of the energy accumulation apparatus when the remaining energy amount of the energy accumulation apparatus acquired in the acquiring the energy amount becomes equal to or smaller than a predetermined amount.

(Item A-16)

A program for causing a computer to execute an estimation method for estimating energy recovery demand of an energy accumulation apparatus,
the estimation method including:
acquiring an energy amount by acquiring a remaining energy amount of the energy accumulation apparatus; and
estimating a demand arising position which is a position at which the energy recovery demand has arisen, based on a low remaining amount position which is a position of the energy accumulation apparatus when the remaining energy amount of the energy accumulation apparatus acquired in the acquiring the energy amount becomes equal to or smaller than a predetermined amount.

(Item A-17)

A computer-readable storage medium having stored thereon the program according to item A-16.

For example, the following matters are disclosed in the present specification.

(Item B-1)

A trial calculation apparatus configured to perform a trial calculation regarding an arrangement of an energy recovery apparatus capable of recovering an accumulated energy amount of an energy accumulation apparatus, the trial calculation apparatus including:
an output unit configured to output: (i) a first output value which is an output value related to a number of the energy recovery apparatuses to be arranged; and (ii) a second output value which is an output value related to a position at which the energy recovery apparatus is to be arranged, based on: (i) a first condition that is a restriction condition related to a cost of an owner or an operator of the energy recovery apparatus and includes a first variation value which is a variation value related to the number of the energy recovery apparatuses; and (ii) a second condition that is a restriction condition related to a convenience of a user and includes a second variation value which is a variation value related to a position of the user of the energy accumulation apparatus.

(Item B-2)

The trial calculation apparatus according to item B-1, wherein
the second condition further includes a third variation value which is a variation value related to the position of the energy recovery apparatus.

(Item B-3)

The trial calculation apparatus according to item B-1 or B-2, further including:
a demand estimation unit configured to estimate energy recovery demand of the energy accumulation apparatus,
wherein the demand estimation unit includes:
an energy amount acquisition unit configured to acquire a remaining energy amount of the energy accumulation apparatus; and
a demand arising position estimation unit configured to estimate a demand arising position which is a position at which the energy recovery demand has arisen, based on a low remaining amount position which is a position of the energy accumulation apparatus when the remaining energy amount of the energy accumulation apparatus acquired by the energy amount acquisition unit becomes equal to or smaller than a predetermined amount.

(Item B-4)

The trial calculation apparatus according to item B-3, further including:
a determination unit configured to determine the arrangement of the energy recovery apparatus capable of recovering the accumulated energy amount of the energy accumulation apparatus,
wherein the determination unit is configured to determine the position at which the energy recovery apparatus is to be arranged based on the demand arising position estimated by the demand arising position estimation unit.

(Item B-5)

The trial calculation apparatus according to item B-4, wherein
the determination unit is configured to determine, further based on a position of an existing energy recovery apparatus that has already been arranged,
the position at which the energy recovery apparatus is to be arranged.

(Item B-6)

A trial calculation method for performing a trial calculation regarding an arrangement of an energy recovery apparatus capable of recovering an accumulated energy amount of an energy accumulation apparatus, the trial calculation method including:
outputting (i) a first output value which is an output value related to the number of the energy recovery apparatuses to be arranged and (ii) a second output value which is an output value related to a position at which the energy recovery apparatus is to be arranged, based on: (i) a first condition that is a restriction condition related to a cost of an owner or an operator of the energy recovery apparatus and includes a first variation value which is a variation value related to a number of the energy recovery apparatuses; and (ii) a second condition that is a restriction condition related to a convenience of a user and includes a second variation value which is a variation value related to a position of the user of the energy accumulation apparatus.

### EXPLANATION OF REFERENCES

10 communication network
22 passenger
24 service provider
30 communication terminal
100 arrangement assistance system
120 vehicle
122 battery
124 vehicle control unit
130 battery replacement apparatus
132 battery accommodation portion
140 assistance server
142 actual measurement data acquisition unit
144 storage unit
146 condition setting unit
148 recovery demand estimation unit
152 prediction data acquisition unit
154 optimum arrangement trial calculation unit
212 map data storage unit
214 road data storage unit
216 existing position storage unit
222 prediction data storage unit
224 actual measurement data storage unit
226 data table
230 probe information
242 remaining capacity information
244 vehicle information
246 usage information
420 path
440 path
520 path
540 path
620 path
640 path
720 path
740 path
822 energy amount acquisition unit
824 position acquisition unit
826 demand arising position estimation unit
832 deviation amount estimation unit
834 evaluation unit
836 arrangement determination unit
842 demand output unit
844 arrangement output unit
922 stop-by position determination unit
924 destination location determination unit
932 first path determination unit
934 second path determination unit
936 deviation amount derivation unit
1010 map
1012 map image
1014 heat map
1016 contour line
1020 map
1030 map
1122 traffic group simulator
1124 optimization solver
1126 trial calculation result output unit
1142 dynamic data
1144 optimum solution data
1222 user ID
1224 time
1226 SOC
1228 area ID
1230 status
1320 arrangement trial calculation data
1340 breakdown data
1522 preprocessing unit
1524 installation number adjustment unit
1526 area information storage unit
1544 optimum solution data
1546 optimum solution data
1622 area ID
1624 information
1626 information
1722 area ID
1724 information
1726 information
1728 information
1800 output result
1820 map
1840 list
1842 number
1843 area ID
1844 information
1845 identification information
1846 information
1847 information
1848 information
1900 output result
1920 calculation result
1922 value
1924 value
1926 value
1928 value
1940 calculation result
1960 calculation result
1980 calculation result
2020 dynamic data storage unit
2030 setting unit
2040 mathematical programming unit
2042 arrangement determination unit
2044 simulation execution unit
2046 objective function calculation unit
2050 optimum solution data output unit
2122 dynamic data reading unit
2124 recovery necessity judgment unit
2126 index value calculation unit
2130 deviation routine execution unit
2132 recovery position determination unit
2134 dynamic data update unit
2136 deviation amount derivation unit
3000 computer
3001 DVD-ROM
3010 host controller
3012 CPU
3014 RAM
3016 GPU
3018 display device
3020 input/output controller
3022 communication interface
3024 hard disk drive
3026 DVD-ROM drive
3030 ROM
3040 input/output chip
3042 keyboard

1. A simulation apparatus configured to perform a simulation of an arrangement of an energy recovery apparatus capable of recovering an accumulated energy amount of an energy accumulation apparatus, the simulation apparatus comprising:
an output unit configured to output a result of the simulation,
wherein the output unit is configured to:
(a) output a first output amount which is an output amount related to a position at which the energy recovery apparatus is to be arranged; or
(b) output a second output amount which is an output amount used for determining the position at which the energy recovery apparatus is to be arranged,
based on at least one of:
(i) a first relational expression which is a relational expression for deriving a cost of an owner or an operator of the energy recovery apparatus and which corresponds to a first variation amount that is a variation amount related to a position of the energy recovery apparatus; and
(ii) a second relational expression which is a relational expression for deriving a convenience of a user or a convenience of a movable body and which corresponds to the first variation amount and a second variation amount that is a variation amount related to dynamics of the user of the energy accumulation apparatus or to dynamics of the movable body configured to move by using energy of the energy accumulation apparatus.

2. The simulation apparatus according to claim 1, wherein
the first variation amount includes a plurality of the variation amounts related to a position of each of a plurality of the energy recovery apparatuses.

3. The simulation apparatus according to claim 1 or 2, wherein
the first variation amount is a first position which is the position of the energy recovery apparatus,
the second variation amount is a second position which is a position of the user or the movable body when energy recovery demand of the energy accumulation apparatus arises, and
the second relational expression is a relational expression for deriving the convenience, a degree of which varies along with a movement of the user or the movable body from the second position to the first position.

4. The simulation apparatus according to claim 3, wherein
the convenience is indicated by an amount having a correlation with a difference between, at least one of, times, costs and energies that are required for the movement in and movement distances in (i) a case where the user or the movable body moves along a first path that reaches a destination of the user or the movable body from the second position and (ii) a case where the user or the movable body moves along a second path that is a path different from the first path and that reaches the destination from the second position via the first position.

5. The simulation apparatus according to claim 3, or wherein
the convenience is indicated by an amount having a correlation with a wait time which is a time during which the user or the movable body stands by for recovering the accumulated energy amount of the energy accumulation apparatus in the energy recovery apparatus, after the user or the movable body moves from the second position to the first position.

6. The simulation apparatus according to claim 1, wherein
the output unit is configured to:
(a) execute first processing for determining the position at which the energy recovery apparatus is to be arranged such that a first objective function including the first relational expression and the second relational expression is minimized or such that a value of the first objective function becomes smaller than a predetermined value; and
(b) (i) output, when a solution whose number is equal to or smaller than a predetermined number is obtained through the first processing, the first output amount based on the solution from the first processing, and (ii) execute, when solutions whose number is more than the predetermined number are obtained through the first processing, second processing for determining the position at which the energy recovery apparatus is to be arranged such that a second objective function placing more importance on the second relational expression than on the first relational expression as compared to the first objective function is minimized or such that a value of the second objective function becomes smaller than a predetermined value, and output the first output amount based on a solution from the second processing.

7. The simulation apparatus according to claim 1, wherein
the output unit is configured to output the first output amount or the second output amount further based on a third relational expression which is a relational expression for deriving a safety of the energy accumulation apparatus and which corresponds to a third variation amount that is a variation amount related to a state of the energy accumulation apparatus.

8. The simulation apparatus according to claim 1, wherein
the output unit is configured to:
execute a program for calculating an optimum solution of an objective function including the first relational expression and the second relational expression, based on a simulation result obtained by simulating dynamics of the movable body that are in each of a plurality of candidate site areas set in a target zone as a target for the arrangement of the energy recovery apparatus and that are in a case where the movable body is capable of moving without considering a recovery of the accumulated energy amount of the energy accumulation apparatus; and
output the first output amount or the second output amount based on the optimum solution.

9. The simulation apparatus according to claim 3, further comprising:
a demand estimation unit configured to estimate energy recovery demand of the energy accumulation apparatus,
wherein the demand estimation unit is configured to determine the second position based on a result of estimating the energy recovery demand.

10. The simulation apparatus according to claim 9, wherein
the demand estimation unit includes:
an energy amount acquisition unit configured to acquire a remaining energy amount of the energy accumulation apparatus; and
a demand arising position estimation unit configured to estimate a demand arising position which is a position at which the energy recovery demand has arisen, based on a low remaining amount position which is a position of the energy accumulation apparatus when the remaining energy amount of the energy accumulation apparatus acquired by the energy amount acquisition unit becomes equal to or smaller than a predetermined amount.

11. The simulation apparatus according to claim 10, further comprising:
a deviation amount estimation unit configured to estimate a deviation amount which is a physical amount due to the movable body stopping by at a stop-by position based on (i) a destination location which is a location of a destination of the movable body and (ii) the stop-by position which is a position of the energy recovery apparatus capable of recovering the accumulated energy amount of the energy accumulation apparatus and at which the movable body has stopped by in movement to the destination.

12. The simulation apparatus according to claim 11, wherein
the deviation amount estimation unit is configured to estimate the deviation amount based on (i) a reference amount determined based on the demand arising position and the destination location and (ii) a stop-by amount determined based on the demand arising position, the stop-by position, and the destination location.

13. The simulation apparatus according to claim 1, wherein
the first variation amount is the position of the energy recovery apparatus or the position and a number of the energy recovery apparatuses, and
the first relational expression is a relational expression into which the first variation amount is input and which is for outputting at least one of an installation cost and an operational cost of the energy recovery apparatus.

14. The simulation apparatus according to claim 1, wherein
at least one of the first relational expression and the second relational expression constitutes at least a part of an objective function of a mathematical programming problem for determining the position at which the energy recovery apparatus is to be arranged.

15. A simulation method of performing a simulation of an arrangement of an energy recovery apparatus capable of recovering an accumulated energy amount of an energy accumulation apparatus, the simulation method comprising:
outputting a result of the simulation,
wherein the outputting includes:
(a) outputting a first output amount which is an output amount related to a position at which the energy recovery apparatus is to be arranged; or
(b) outputting a second output amount which is an output amount used for determining the position at which the energy recovery apparatus is to be arranged,
based on at least one of:
(i) a first relational expression which is a relational expression for deriving a cost of an owner or an operator of the energy recovery apparatus and which corresponds to a first variation amount that is a variation amount related to a position of the energy recovery apparatus; and
(ii) a second relational expression which is a relational expression for deriving a convenience of a user or a movable body and which corresponds to the first variation amount and a second variation amount that is a variation amount related to dynamics of the user of the energy accumulation apparatus or to dynamics of the movable body configured to move by using energy of the energy accumulation apparatus.

16. A computer-readable storage medium having stored thereon a program for causing a computer to execute a simulation method of performing a simulation of an arrangement of an energy recovery apparatus capable of recovering an accumulated energy amount of an energy accumulation apparatus, the simulation method comprising:
outputting a result of the simulation,
wherein the outputting includes:
(a) outputting a first output amount which is an output amount related to a position at which the energy recovery apparatus is to be arranged; or
(b) outputting a second output amount which is an output amount used for determining the position at which the energy recovery apparatus is to be arranged,
based on at least one of:
(i) a first relational expression which is a relational expression for deriving a cost of an owner or an operator of the energy recovery apparatus and which corresponds to a first variation amount that is a variation amount related to a position of the energy recovery apparatus; and
(ii) a second relational expression which is a relational expression for deriving a convenience of a user or a movable body and which corresponds to the first variation amount and a second variation amount that is a variation amount related to dynamics of the user of the energy accumulation apparatus or to dynamics of the movable body configured to move by using energy of the energy accumulation apparatus.

17. The simulation apparatus according to claim 2, wherein
the first variation amount is a first position which is the position of the energy recovery apparatus,
the second variation amount is a second position which is a position of the user or the movable body when energy recovery demand of the energy accumulation apparatus arises, and
the second relational expression is a relational expression for deriving the convenience, a degree of which varies along with a movement of the user or the movable body from the second position to the first position.

18. The simulation apparatus according to claim 4, wherein
the convenience is indicated by an amount having a correlation with a wait time which is a time during which the user or the movable body stands by for recovering the accumulated energy amount of the energy accumulation apparatus in the energy recovery apparatus, after the user or the movable body moves from the second position to the first position.

19. The simulation apparatus according to claim 2, wherein
the output unit is configured to:
(a) execute first processing for determining the position at which the energy recovery apparatus is to be arranged such that a first objective function including the first relational expression and the second relational expression is minimized or such that a value of the first objective function becomes smaller than a predetermined value; and
(b) (i) output, when a solution whose number is equal to or smaller than a predetermined number is obtained through the first processing, the first output amount based on the solution from the first processing, and (ii) execute, when solutions whose number is more than the predetermined number are obtained through the first processing, second processing for determining the position at which the energy recovery apparatus is to be arranged such that a second objective function placing more importance on the second relational expression than on the first relational expression as compared to the first objective function is minimized or such that a value of the second objective function becomes smaller than a predetermined value, and output the first output amount based on a solution from the second processing.

20. The simulation apparatus according to claim 2, wherein
the output unit is configured to output the first output amount or the second output amount further based on a third relational expression which is a relational expression for deriving a safety of the energy accumulation apparatus and which corresponds to a third variation amount that is a variation amount related to a state of the energy accumulation apparatus.
